(19) United States
(12) Patent Application Publication
(10) Pub. No.: US 2025/0378871 A1
(43) Pub. Date: Dec. 11, 2025

(54) MEMORY DEVICE

(71) Applicant: Samsung Electronics Co., Ltd., Suwon-si (KR)

(72) Inventors: Youngsik LEE, Suwon-si (KR); Yong-Wook KIM, Suwon-si (KR); Tae Hee HAN, Suwon-si (KR)

(73) Assignees: Samsung Electronics Co., Ltd., Suwon-si (KR); RESEARCH & BUSINESS FOUNDATION SUNGKYUNKWAN UNIVERSITY, Gyeonggi-do (KR)

(21) Appl. No.: 18/989,553

(22) Filed: Dec. 20, 2024

(30) Foreign Application Priority Data
Jun. 10, 2024 (KR) 10-2024-0075303

(51) Int. Cl. G11C 11/4078; G11C 11/406

(52) U.S. Cl. CPC G11C 11/4078; G11C 11/40603

(57) ABSTRACT

A memory device includes a memory cell array connected to a plurality of wordlines, and a row hammering protector including processing circuitry configured to probabilistically perform, based on an adjacent wordline activation count with respect to each of the plurality of wordlines during a first bank refresh period, an additional refresh operation with respect to each of the plurality of wordlines within a second bank refresh period after the first bank refresh period.

### CROSS-REFERENCE TO RELATED APPLICATION

This application claims priority to and the benefit of Korean Patent Application No. 10-2024-0075303 filed in the Korean Intellectual Property Office on Jun. 10, 2024, the entire contents of which are incorporated herein by reference.

### BACKGROUND

### (a) Field

Example embodiments of the inventive concepts relate to a semiconductor memory device. More specifically, example embodiments of the inventive concepts relate to a memory device capable of defending against row hammering.

### (b) Description of the Related Art

Volatile memory devices such as dynamic random-access memory (DRAM) may store data in the form of charges charged in memory cells. Charges charged in memory cells of a volatile memory device may leak for various reasons. Accordingly, the DRAM can perform a refresh operation to recharge the charge stored in the memory cell.

Recently, in accordance with the trend of higher integration of volatile memory devices, the interval between a plurality of wordlines controlling the memory cell is gradually narrowing. Accordingly, when one wordline is activated, a coupling phenomenon in which the amount of charge stored in memory cells connected to wordlines adjacent thereto unintentionally changes may occur. In particular, when wordlines (e.g., an aggressor wordlines) adjacent to a specific wordline (e.g., an victim wordline) are activated repeatedly within a short period of time, the probability of the data stored in the memory cells connected to the victim wordline being damaged may increase. Damage to the data stored in the memory cells connected to the victim wordline in this manner may be referred to as row hammering or a row hammering attack.

### SUMMARY

Example embodiments of the inventive concepts are intended to solve the technical object described above. For example, some example embodiments of the inventive concepts provide a memory device capable of defending against row hammering.

According to some example embodiments of the inventive concepts, a memory device may include a memory cell array connected to a plurality of wordlines, and a row hammering protector including processing circuitry configured to probabilistically perform, based on an adjacent wordline activation count with respect to each of the plurality of wordlines during a first bank refresh period, an additional refresh operation with respect to each of the plurality of wordlines within a second bank refresh period after the first bank refresh period.

According to some example embodiments of the inventive concepts, a memory device configured to operate in response to control from an external device may include a memory cell array connected to a plurality of wordlines, and processing circuitry configured to generate a first count value by counting the number of times of an activation command for second and third wordlines adjacent to a first wordline among the plurality of wordlines is received from the external device, between a first time point at which a first bank refresh command is received from the external device and a second time point at which a second bank refresh command is received from the external device determine a first probability corresponding to the first count value, and issue a first row refresh command for the first wordline according to the first probability, at a fourth time point between the second time point and a third time point at which a third bank refresh command is received from the external device.

A memory device configured to receive first and second bank refresh commands from an external device at first and second time points, respectively, may include a memory cell array connected to first and second aggressor wordlines, and a victim wordline located between the first and second aggressor wordlines, and processing circuitry configured to probabilistically issue, based on a number of times of activation commands for the first and second aggressor wordlines are received between the first and the second time points, a row refresh command for the victim wordline at each time interval from the second time point until a third bank refresh command is received.

### BRIEF DESCRIPTION OF THE DRAWINGS

FIG. 1 is a block diagram showing a memory system according to some example embodiments.

FIG. 2 is a block diagram showing the memory device of FIG. 1 in more detail.

FIG. 3 is a block diagram showing the memory cell array of FIG. 2 in more detail.

FIG. 4 is a timing diagram showing the operation of the memory device of FIG. 2 according to some example embodiments.

FIG. 5 is a block diagram showing the row hammering protector of FIG. 2 according to some example embodiments in more detail.

FIG. 6 is a block diagram showing the configuration of the row hammering protection circuit of FIG. 5 in more detail.

FIG. 7 is a drawing showing the global probability table of FIG. 5.

FIG. 8 is a graph showing a relationship of the probability of issuing the row refresh command with respect to the count value.

FIG. 9 is a timing diagram showing the operation of memory device according to some example embodiments.

FIG. 10 and FIG. 11 are timing diagrams showing the partial time period of FIG. 9 in more detail.

FIG. 12 is a timing diagram showing the operation of memory device according to some example embodiments.

FIG. 13 is a block diagram showing the row hammering protector of FIG. 2 according to some example embodiments in more detail.

FIG. 14 is a drawing showing a relationship of the local probability table and global probability table of FIG. 13 according to some example embodiments.

FIG. 15 is a drawing showing a method of updating the local probability table of FIG. 13 according to some example embodiments.

FIG. 16 is a block diagram showing the row hammering protector of FIG. 2 according to some example embodiments in more detail.

FIG. 17 and FIG. 18 are drawings showing the relationship of the adjustment weight table and local probability table of FIG. 16 according to some example embodiments.

FIG. 19 and FIG. 20 are timing diagrams showing the operation of the memory device according to some example embodiments of FIG. 18.

FIG. 21 is a timing diagram showing the operation of the row hammering protection circuit of FIG. 2 according to some example embodiments.

FIG. 22 is a timing diagram showing the operation of the memory device during the extended bank refresh period of FIG. 21 in more detail.

### DETAILED DESCRIPTION

Hereinafter, some example embodiments will be described in detail and clearly to such an extent that one skilled in the art may easily carry out the inventive concepts. The details such as components and structures described in the specification are merely provided to assist the overall understanding of some example embodiments. Therefore, it should be apparent to those skilled in the art that various changes and modifications of the example embodiments described herein may be made without departing from the scope and spirit of the inventive concepts. Moreover, the descriptions of well-known functions and structures are omitted for the sake of clarity and brevity. In the following drawings or in the detailed description, components may be connected to any other components except for components that are illustrated in drawings or are described in the detailed description. The terms described below are terms defined in consideration of the functions and are not limited to a specific function. The definitions of the terms should be determined based on the contents throughout the specification.

Components that are described in the detailed description with reference to the terms “driver”, “controller”, “block”, etc. may be implemented with software, hardware, or a combination thereof. For example, the software may be a machine code, firmware, an embedded code, and/or application software. For example, the hardware may include an electrical circuit, an electronic circuit, a processor, a microprocessor, a computer, integrated circuit cores, a pressure sensor, an inertial sensor, a microelectromechanical system (M EMS), a passive element, and/or a combination thereof.

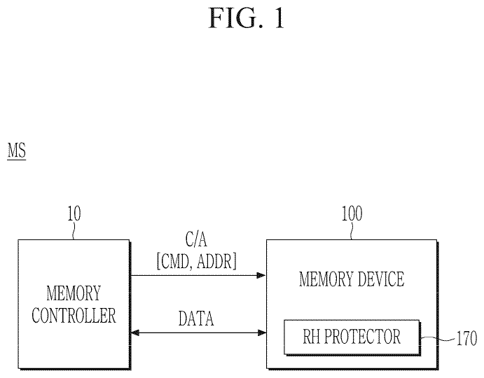

FIG. 1 is a block diagram showing a memory system according to some example embodiments of the inventive concepts. Referring to FIG. 1, memory system MS may include a memory controller 10, which is a host device, and/or a memory device 100.

In some example embodiments, the memory controller 10 may be included in one of various types of processors such as a central processing unit (CPU), a graphic processing unit (GPU), and/or the like.

For a more concise description, hereinafter, it is assumed that the memory device 100 is a dynamic random access memory (DRAM) and the memory controller 10 and the memory device 100 communicate with each other based on a low power double data rate (LPDDR) interface. However, example embodiments are not limited thereto. For example, the memory controller 10 and the memory device 100 may communicate with each other based on low-power double data rate (LPDDR) interface.

The memory controller 10 may store data DATA in the memory device 100, or may read the data DATA from the memory device 100. For example, the memory controller 10 may control the memory device 100 by transmitting various types of commands CMD and/or addresses ADDR to the memory device 100 based on command/address signals C/A. That is, the memory controller 10 may control the memory device 100 by issuing the various types of commands CMD and/or addresses ADDR in form of the command/address signals C/A.

The memory device 100 may include a plurality of memory cells. The plurality of memory cells may be connected to a plurality of wordlines and/or a plurality of bitlines.

In some example embodiments, the memory device 100 may correspond to one memory bank. However, example embodiments are not limited thereto.

The memory device 100 may include a row hammering protector (RH protector) 170. The row hammering protector 170 may determine whether there is a possibility that data stored in the memory device 100 is likely to be damaged due to row hammering. When there is a possibility that the data stored in the memory device 100 is likely to be damaged due to row hammering, the row hammering protector 170 may perform an additional refresh operation, and thereby protect data stored in memory device 100. A detailed configuration and operation of the row hammering protector 170 will be hereinafter described in detail with reference to the drawings.

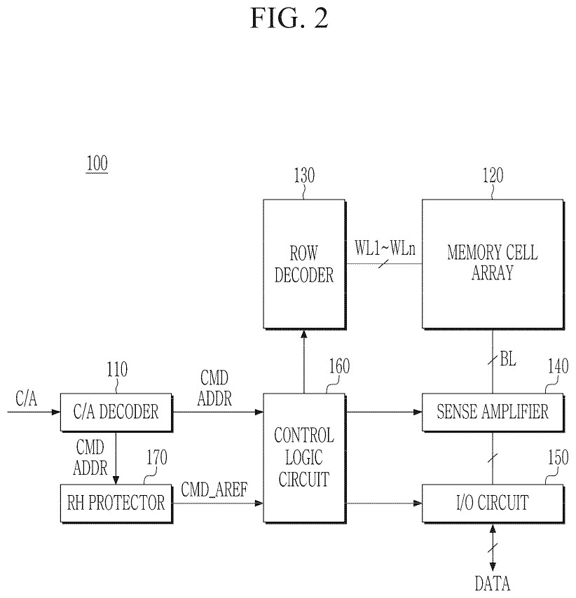

FIG. 2 is a block diagram showing the memory device of FIG. 1 in more detail. Referring to FIG. 2, the memory device 100 may include a command/address decoder (C/A decoder) 110, a memory cell array 120, a row decoder 130, a sense amplifier 140, an input/output circuit (I/O circuit) 150, a control logic circuit 160, and/or the row hammering protector 170.

The command/address decoder 110 may receive the command/address signals C/A provided from the memory controller 10. The command/address decoder 110 may decode the command/address signals C/A into the command CMD and/or the address ADDR.

The command CMD may include various types of commands such as a read command, a write command, an activation command and/or, a bank refresh command. The address ADDR may include a bank address, a row address, and/or a column address. However, example embodiments are not limited thereto, and the command/address signals C/A may represent more diverse types of commands and/or addresses.

The memory cell array 120 may include a plurality of memory cells arranged in a row direction and a column direction. The plurality of memory cells may be connected to the plurality of wordlines WL extending in the row direction and/or a plurality of bit lines BL extending in the column direction. For example, the memory cell array 120 may be connected to first to n-th wordlines WL1 to WLn.

The row decoder 130 may control the plurality of wordlines WL. For example, the row decoder 130 may activate one of the plurality of wordlines WL based on the row address.

The sense amplifier 140 may be connected to the memory cell array 120 through the plurality of bitlines BL. The sense amplifier 140 may temporarily store data provided from the memory cell array 120. For example, the sense amplifier 140 may temporarily store data stored in memory cells connected to an activated wordline.

In some example embodiments, the sense amplifier 140 may restore the data provided from the memory cell array 120, in the memory cell array 120. For example, in response to the control of the control logic circuit 160, the sense amplifier 140 may restore data in memory cells connected to the activated wordlines.

The I/O circuit 150 may receive the data DATA from the memory controller 10, and/or may transmit the data DATA to the memory controller 10. For example, the I/O circuit 150 may write the data DATA received from the memory controller 10 in the memory cell array 120 through the sense amplifier 140, and/or may output the data DATA stored in the sense amplifier 140 to the memory controller 10.

The control logic circuit 160 may receive the command CMD and/or the address ADDR from the command/address decoder 110. The control logic circuit 160 may control an overall operation of the memory device 100, based on the command CMD and/or the address ADDR.

In some example embodiments, in response to the bank refresh command, the control logic circuit 160 may control the row decoder 130 and/or the sense amplifier 140 so that all memory cells in the memory cell array 120 are refreshed.

In some example embodiments, in response to the activation command, the control logic circuit 160 may provide the row address corresponding to the activation command to the row decoder 130. In this case, the row decoder 130 may activate the wordline corresponding to the row address.

The row hammering protector 170 may receive the command CMD and/or the address ADDR from the command/address decoder 110. For example, the row hammering protector 170 may receive a same command CMD and/or a same address ADDR as provided to the control logic circuit 160. For a more concise description, some example embodiments in which the command/address decoder 110 provides both the command CMD and the address ADDR to each of the row hammering protector 170 and the control logic circuit 160 has been illustrated in FIG. 2, however example embodiments are not limited thereto. For example, the row hammering protector 170 may receive the command CMD and/or the address ADDR from the control logic circuit 160, and/or may obtain the command CMD and/or the address ADDR by sniffing the command CMD and/or the address ADDR provided to the control logic circuit 160.

The row hammering protector 170 may determine a wordline connected to the memory cell storing data having high a possibility of being damaged due to row hammering, based on the command CMD and/or the address ADDR. For example, the row hammering protector 170 may monitor the number of “adjacent wordline activations” with respect to each, or one or more, of the first to n-th wordlines WL1 to WLn after the last bank refresh command is provided from the memory controller 10. More specifically, with respect to each, or one or more, of the first to n-th wordlines WL1 to WLn, the row hammering protector 170 may monitor the number of times the activation commands for adjacent wordlines are issued from the memory controller 10. The row hammering protector 170 may determine a wordline corresponding to a great number of adjacent wordline activations as a wordline connected to the memory cell storing data having a high possibility of being damaged due to row hammering.

The row hammering protector 170 may perform a refresh operation with respect to the wordline connected to the memory cell storing data having a high possibility of being damaged due to row hammering. For example, the row hammering protector 170 may issue an additional refresh command CMD_AREF with respect to one or more wordline connected to the memory cell storing data having a high possibility of being damaged due to row hammering. The row hammering protector 170 may provide the additional refresh command CMD_AREF to the control logic circuit 160.

The control logic circuit 160 may receive the additional refresh command CMD_AREF. In this case, the control logic circuit 160 may control the row decoder 130 and/or the sense amplifier 140 so that the memory cell storing data having a high possibility of is damaged due to row hammerings being refreshed. For example, the control logic circuit 160 may control the row decoder 130, and may sequentially activate one or more wordlines. The control logic circuit 160 may control the sense amplifier 140, and may restore data in memory cells connected to the activated wordlines.

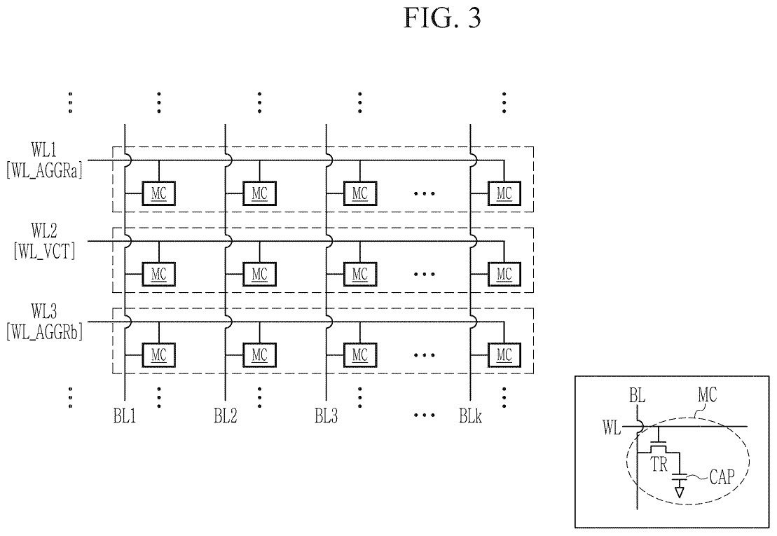

FIG. 3 is a block diagram showing the memory cell array of FIG. 2 in more detail. Referring to FIG. 1 to FIG. 3, the memory cell array 120 may include a plurality of memory cells MC. The plurality of memory cells MC may form a matrix structure arranged in a row direction and a column direction. Hereinafter, for a more concise description, memory cells arranged in the same row of the memory cell array 120 will be referred to as a ‘memory cell row’.

The plurality of memory cells MC may be connected to the plurality of wordlines WL. For a more concise description, FIG. 3 illustrates, as an example, the adjacent first to third wordlines WL1 to WL3 and memory cells connected thereto, but example embodiments are not limited thereto. For example, example embodiments are not limited to the number of wordlines and the number of memory cells.

The plurality of memory cells MC may be connected to the plurality of bitlines BL. For example, the plurality of memory cells MC may be connected to first to m-th bitlines BL1 to BLm.

Each, or one or more, of the plurality of memory cells MC may be a DRAM cell. For example, each, or one or more, of the plurality of memory cells MC may include a transistor TR and/or a capacitor CAP, and may store data based on the amount of charge stored in the capacitor CAP.

The amount of charge stored in each, or one or more, of the plurality of memory cells MC may unintentionally change as a wordline connected to another adjacent memory cell is activated. For example, as the first and third wordlines WL1 and WL3 are activated, the amount of charge of the memory cells MC connected to a second wordline WL2 may increase or decrease. In particular, although the memory cells connected to the second wordline WL2 are not refreshed, when the first and third wordlines WL1 and WL3 are repeatedly activated, the amount of charge of the memory cells MC connected to the second wordline WL2 may greatly increase or greatly decrease. In this case, data represented by the memory cells MC connected to the second wordline WL2 may be damaged.

Hereinafter, for a more concise description, the wordline connected to the memory cells whose amount of charge unintentionally changes will be referred to as a victim wordline WL_VCT, and the wordlines adjacent to the victim wordline WL_VCT will be referred to as first and second aggressor wordlines WL_AGGRa and WL_AGGRb, respectively. For example, referring to FIG. 3, the second wordline WL2 may be the victim wordline WL_VCT, and the first and third wordlines WL1 and WL3 may be referred to as the first and second aggressor wordlines WL_AGGRa and WL_AGGRb, respectively.

For a more concise description, hereinafter, it is assumed that the wordlines immediately adjacent to the victim wordline WL_VCT are the aggressor wordlines WL_AGGR. However, example embodiments are not limited thereto, and wordlines spaced apart from the victim wordline WL_VCT by one or more wordline may also be the aggressor wordline WL_AGGR for the victim wordline WL_VCT. For example, a first wordline WL1 may be an aggressor wordline with respect to a third wordline WL3, and/or the third wordline WL3 may be an aggressor wordline with respect to the first wordline WL1. That is, example embodiments are not limited to the interval between the victim wordline WL_VCT and the aggressor wordline WL_AGGR.

In some example embodiments, although the aggressor wordlines WL_AGGRa and WL_AGGRb are repeatedly activated, when the memory cells MC connected to the victim wordline WL_VCT are refreshed more frequently (e.g., when the memory cells MC connected to the victim wordline WL_VCT are additionally refreshed), the probability of damage to the data stored in the memory cells MC connected to the victim wordline WL_VCT may be reduced or minimized. In this way, the row hammering protector 170 may perform the additional refresh operation for the victim wordline WL_VCT, and thereby reduce or minimize the probability of damage to the data stored in the memory cells MC connected to the victim wordline WL_VCT.

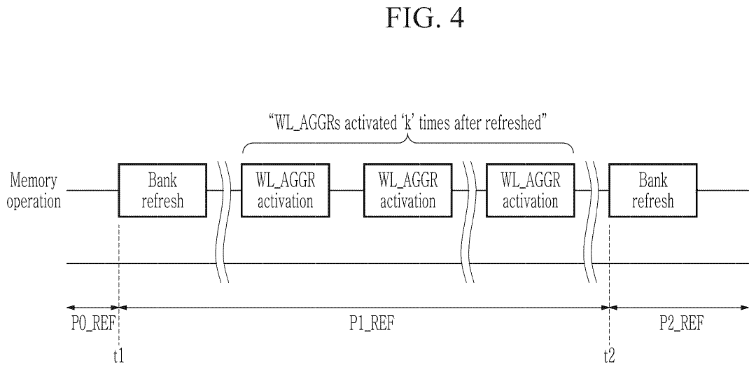

FIG. 4 is a timing diagram showing the operation of the memory device of FIG. 2 according to some example embodiments. Referring to FIG. 1 to FIG. 4, at a first time point t1, the memory device 100 may perform a bank refresh operation. For example, the memory device 100 may perform the bank refresh operation in response to the bank refresh command provided from the memory controller 10. In this case, all memory cells included in the memory cell array 120 may be refreshed. Similarly, at a second time point t2 after the first time point t1, the memory device 100 may perform the bank refresh operation. Hereinafter, for a more concise description, a time period between the first time point t1 and the second time point t2 may be referred to as a first bank refresh period P1_REF.

However, during the first bank refresh period P1_REF, the memory device 100 may repeatedly perform the aggressor wordline WL_AGGR activation operation. For example, during the first bank refresh period P1_REF, the memory device 100 may activate a first aggressor wordline WL_AGGRa and/or a second aggressor wordline WL_AGGRb, ‘k’ times in total.

The probability of damage to the data stored in memory cells connected to the victim wordline WL_VCT may vary depending on the value of ‘k’. For example, when the ‘k’ value is large, the probability of damage to the data stored in memory cells connected to the victim wordline WL_VCT may be high; and when the ‘k’ value is small, the probability that the data stored in memory cells connected to the victim wordline WL_VCT is to be damaged may be low.

In some example embodiments, during the first bank refresh period P1_REF, the row hammering protector 170 may perform the additional refresh operation with respect to the victim wordline WL_VCT. That is, between the first time point t1 and the second time point t2, the row hammering protector 170 may additionally refresh the memory cells MC connected to the victim wordline WL_VCT. In this case, even if the ‘k’ value is large, the possibility of damage to the data stored in memory cells connected to the victim wordline WL_VCT the first bank refresh period P1_REF may be reduced or minimized. A method in which the row hammering protector 170 additionally refreshes the memory cells MC connected to the victim wordline WL_VCT will be hereinafter described in detail with reference to the drawings.

In some example embodiments, the row hammering protector 170 may perform the additional refresh operation with respect to the victim wordline WL_VCT within the first bank refresh period P1_REF based on the number of times by which the aggressor wordline WL_AGGR is activated during a 0-th bank refresh period P0_REF preceding the first bank refresh period P1_REF. For example, the row hammering protector 170 may perform the additional refresh operation with respect to each, or one or more, of the first to n-th wordlines WL1 to WLn within the first bank refresh period P1_REF, based on the number of the adjacent wordline activations corresponding to each, or one or more, of the first to n-th wordlines WL1 to WLn during the 0-th bank refresh period P0_REF. Similarly, the row hammering protector 170 may perform the additional refresh operation with respect to each, or one or more, of the first to n-th wordlines WL1 to WLn within a second bank refresh period P2_REF, based on the number of the adjacent wordline activations corresponding to each, or one or more, of the first to n-th wordlines WL1 to WLn during the first bank refresh period P1_REF. That is, throughout a plurality of bank refresh periods, the row hammering protector 170 may perform the additional refresh operation with respect to each, or one or more, of the first to n-th wordlines WL1 to WLn, based on the number of adjacent wordline activations with respect to each, or one or more, of the first to n-th wordlines WL1 to WLn during the previous bank refresh period.

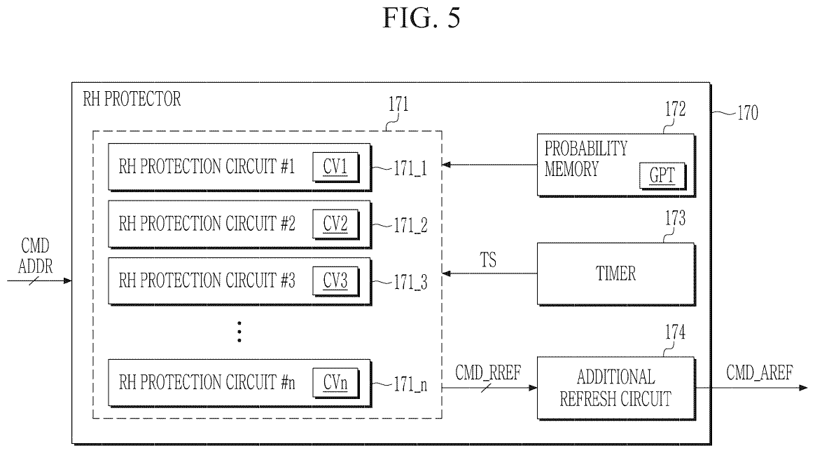

FIG. 5 is a block diagram showing the row hammering protector of FIG. 2 according to some example embodiments in more detail. The row hammering protector 170 may include a plurality of row hammering protection circuits 171, a probability memory 172, a timer 173, and/or an additional refresh circuit 174. Hereinafter, referring to FIG. 1 to FIG. 5, some example embodiments in which the row hammering protector 170 performs the additional refresh operation with respect to the victim wordline WL_VCT within the first bank refresh period P1_REF will be described in detail, as an example.

The plurality of row hammering protection circuits 171 may include first to n-th row hammering protection circuits 171_1 to 171_n. The first to n-th row hammering protection circuits 171_1 to 171_n may correspond to the first to n-th wordlines WL1 to WLn, respectively.

The first to n-th row hammering protection circuits 171_1 to 171_n may perform row hammering protection operations with respect to different wordline from each other. For example, a first row hammering protection circuit 171_1 may defend against row hammering for the first wordline WL1; and a second row hammering protection circuit 171_2 may defend against row hammering for the second wordline WL2. Similarly, the third to n-th row hammering protection circuits 171_3 to 171_n may defend against row hammering for the third to n-th wordlines WL3 to WLn, respectively. In other words, with the viewpoint such corresponding wordline is the victim wordline WL_VCT, the first to n-th row hammering protection circuits 171_1 to 171_n may respectively defend against row hammering for the first to n-th wordlines WL1 to WLn.

For example, the first to n-th row hammering protection circuits 171_1 to 171_n may respectively generate first to n-th count values CV1 to CVn by counting the number of adjacent wordline activations for the first to n-th wordlines WL1 to WLn, respectively. For example, the second row hammering protection circuit 171_2 may generate a second count value CV2 by counting the number of times the activation command for the wordlines adjacent to the second wordline WL2 (e.g., the first and third wordlines WL1 and WL3) are received during the 0-th bank refresh period P0_REF.

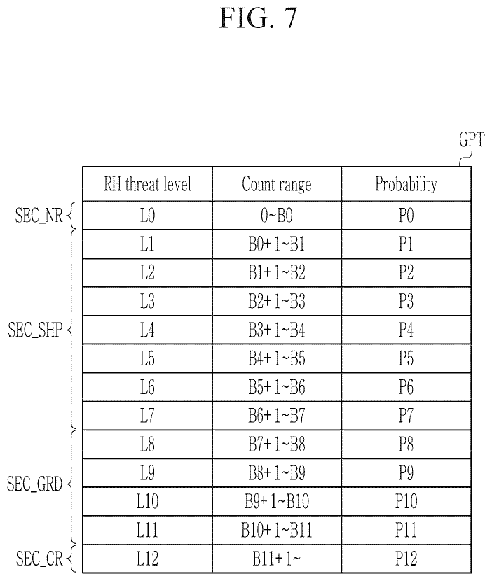

The probability memory 172 may store a global probability table GPT including a plurality of probabilities corresponding to a plurality of count ranges, respectively. The configuration of the global probability table GPT will be hereinafter described in more detail with reference to FIG. 7.

Each, or one or more, of the first to n-th row hammering protection circuits 171_1 to 171_n may identify a probability corresponding to the count value CV from among the plurality of probabilities included in the global probability table GPT. For example, the second row hammering protection circuit 171_2 may identify a probability corresponding to the second count value CV2 based on the global probability table GPT.

The timer 173 may measure a time length that has elapsed from the time point at which the bank refresh command is provided from the memory controller 10. When a predetermined, or alternately given, time length has elapsed from the time point at which the bank refresh command is provided from the memory controller 10, the timer 173 may provide a trigger signal TS to each, or one or more, of the plurality of row hammering protection circuits 171. For example, after the predetermined, or alternately given, time length has elapsed from the first time point t1, the timer 173 may provide the trigger signal TS to each, or one or more, of the first to n-th row hammering protection circuits 171_1 to 171_n.

In response to the trigger signal TS, the first to n-th row hammering protection circuits 171_1 to 171_n may issue a row refresh command CMD_RREF with respect to the corresponding wordline, according to the probability determined based on the global probability table GPT. For example, the second row hammering protection circuit 171_2 may probabilistically issue the row refresh command CMD_RREF for the second wordline WL2 in response to the trigger signal TS. In this way, the first to n-th row hammering protection circuits 171_1 to 171_n may probabilistically issue row refresh commands CMD_RREF with respect to the first to n-th wordlines WL1 to WLn, respectively.

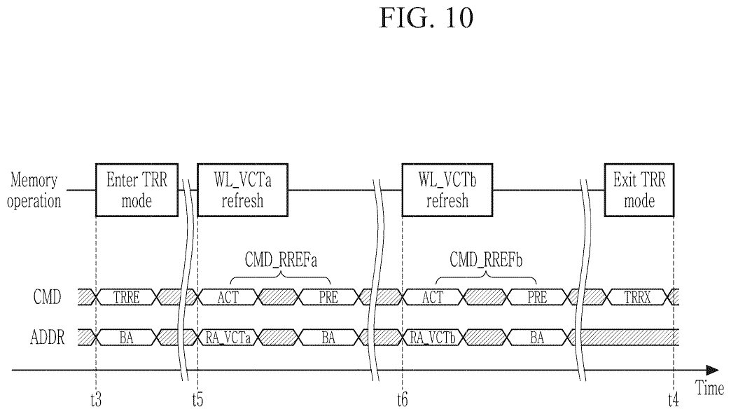

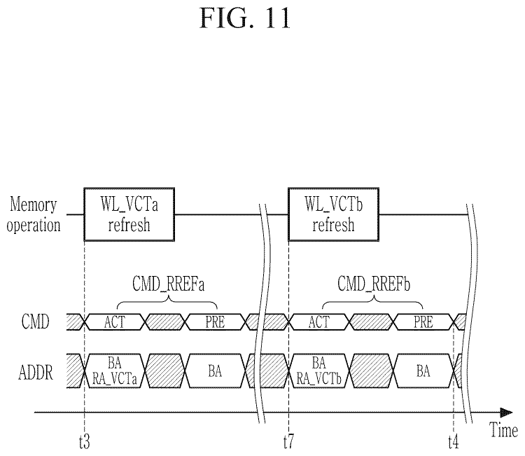

The additional refresh circuit 174 may receive one or more row refresh commands CMD_RREF provided from the first to n-th row hammering protection circuits 171_1 to 171_n. The additional refresh circuit 174 may issue the additional refresh command CMD_AREF based on the one or more row refresh commands CMD_RREF. The additional refresh circuit 174 may provide the additional refresh command CMD_AREF to the control logic circuit 160. In this case, the control logic circuit 160 may sequentially perform additional refresh operations with respect to one or more wordlines. The method in which the control logic circuit 160 sequentially performs the additional refresh operations with respect to one or more wordlines will be hereinafter described in more detail with reference to FIG. 10 and FIG. 11.

In some example embodiments, in a command sequence of the additional refresh command CMD_AREF, the one or more row refresh commands CMD_RREF provided in the additional refresh circuit 174 may be included. In this case, the additional refresh circuit 174 may include a command queue storing the one or more row refresh commands CMD_RREF.

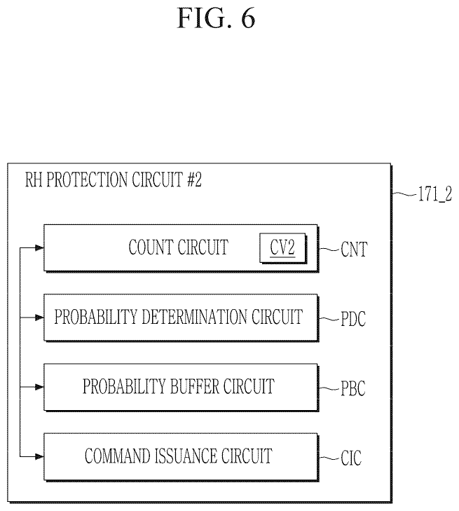

FIG. 6 is a block diagram showing the configuration of the row hammering protection circuit of FIG. 5 in more detail. Hereinafter, for brevity of description, referring to FIG. 1 to FIG. 6, a configuration and operation of the second row hammering protection circuit 171_2 will be described in detail, as an example. However, example embodiments are not limited thereto, and each of the first to n-th row hammering protection circuits 171_1 to 171_n may be configured in a similar manner.

The second row hammering protection circuit 171_2 may include a count circuit CNT, a probability determination circuit PDC, a probability buffer circuit PBC, and/or a command issuing circuit CIC.

The count circuit CNT may generate the second count value CV2 by counting the number of times of which the activation commands for the aggressor wordlines WL_AGGR (e.g., the first and/or third wordlines WL1 and/or WL3) are received from the memory controller 10 during the 0-th bank refresh period P0_REF. For example, the count circuit CNT may accumulate the second count value CV2 until the first time point t1 at which the 0-th bank refresh period P0_REF is terminated (e.g., time point at which the bank refresh command is received from the memory controller 10).

The probability determination circuit PDC may determine the probability corresponding to the second count value CV2 based on the global probability table GPT. For example, the probability determination circuit PDC may look-up a probability corresponding to the second count value CV2 from the global probability table GPT.

The probability buffer circuit PBC may store the probability determined by the probability determination circuit PDC. The probability buffer circuit PBC may store the probability determined by the probability determination circuit PDC until the trigger signal TS is received.

In response to the trigger signal TS, the command issuing circuit CIC may issue the row refresh command CMD_RREF for the second wordline WL2 based on the probability stored in the probability buffer circuit PBC. For example, according to the probability stored in the probability buffer circuit PBC, the command issuing circuit CIC may or may not issue the row refresh command CMD_RREF and address with respect to the second wordline WL2.

That is, according to some example embodiments, based on a count value of which the activation commands for the first and third wordlines WL1 and WL3 are received during the 0-th bank refresh period P0_REF, the second row hammering protection circuit 171_2 may determine whether to perform the additional refresh operation with respect to the second wordline WL2 within the first bank refresh period P1_REF.

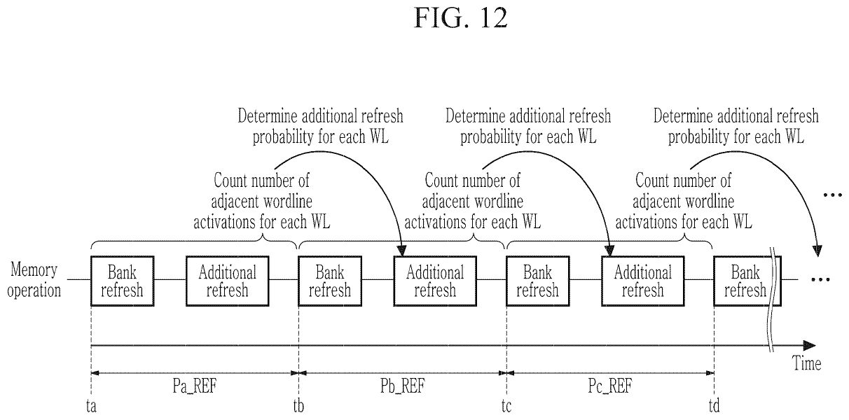

In some example embodiments, throughout a plurality of bank refresh periods, based on the number of adjacent wordline activations for the second wordline WL2 during the previous bank refresh period, the second row hammering protection circuit 171_2 may determine whether to perform the additional refresh operation with respect to the second wordline WL2 within the subsequent bank refresh period. For example, even during the first bank refresh period P1_REF, the count circuit CNT may generate the second count value CV2 in a similar manner as described above. In this case, the second row hammering protection circuit 171_2 may determine whether to perform the additional refresh operation for the second wordline WL2 within the second bank refresh period P2_REF based on the second count value CV2. The operation of the row hammering protector 170 throughout a plurality of bank refresh periods will be hereinafter described in more detail with reference to FIG. 12.

FIG. 7 is a drawing showing the global probability table of FIG. 5. Referring to FIG. 1 to FIG. 7, the global probability table GPT may include 0-th to twelfth probabilities P0 to P12 respectively corresponding to 0-th to twelfth row hammering threat levels L0 to L12. For a more concise description, FIG. 7 illustrates, as an example, that the global probability table GPT storing 13 row hammering threat levels and 13 probabilities corresponding thereto, but example embodiments are not limited to the numbers of row hammering threat levels and/or probabilities included in the global probability table GPT.

Each of the 0-th to twelfth row hammering threat levels L0 to L12 may correspond to different count ranges. That is, each of the 0-th to twelfth row hammering threat levels L0 to L12 may correspond to different count ranges. In this case, count ranges corresponding to the 0-th to twelfth row hammering threat levels L0 to L12 may be consecutive to each other, and may not overlap with each other. For example, the 0-th row hammering threat level L0 may correspond to the count range of ‘0 to B0’, and a first row hammering threat level L1 may correspond to the count range of ‘B0+1 to B1’. In such way, an eleventh row hammering threat level L11 may correspond to the count range of ‘B10+1 to B11’. A twelfth row hammering threat level L12 may correspond to the count range of ‘B11+1 and above’.

Upper limit values of the count ranges corresponding to the 0-th to eleventh row hammering threat levels L0 to L11 may be B0 to B11, respectively. B0 to B11 may be integers greater than or equal to 0, and may form an increasing sequence. For example, B1 may be an integer greater than B0, and B2 may be an integer greater than B1. In this case, the count range corresponding to the first row hammering threat level L1 may be higher than the count range corresponding to the 0-th row hammering threat level L0, and the count range corresponding to a second row hammering threat level L2 may be higher than the count range corresponding to the first row hammering threat level L1.

Each, or one or more of, of the probability determination circuit PDC of the first to n-th row hammering protection circuits 171_1 to 171_n may identify the probability corresponding to the count value CV from the global probability table GPT. For example, when the second count value CV2 is ‘B3’, the probability determination circuit PDC included in the second row hammering protection circuit 171_2 may identify a third probability P3 corresponding to the count range including ‘B3’. In this case, the second row hammering protection circuit 171_2 may determine the identified third probability P3 as the probability for issuing the row refresh command CMD_RREF with respect to the second wordline WL2 within the first bank refresh period P1_REF. Hereinafter, for a more concise description, the operation of the second row hammering protection circuit 171_2 will be described in detail, as an example. However, example embodiments are not limited thereto, and the first to n-th row hammering protection circuits 171_1 to 171_n may also determine the probability to issue the row refresh command CMD_RREF based on the global probability table GPT.

In some example embodiments, each, or one or more, of the first to n-th row hammering protection circuits 171_1 to 171_n may share the global probability table GPT. That is, each, or one or more, of the first to n-th row hammering protection circuits 171_1 to 171_n may determine the probability to issue the row refresh command CMD_RREF with respect to the corresponding wordline based on the global probability table GPT.

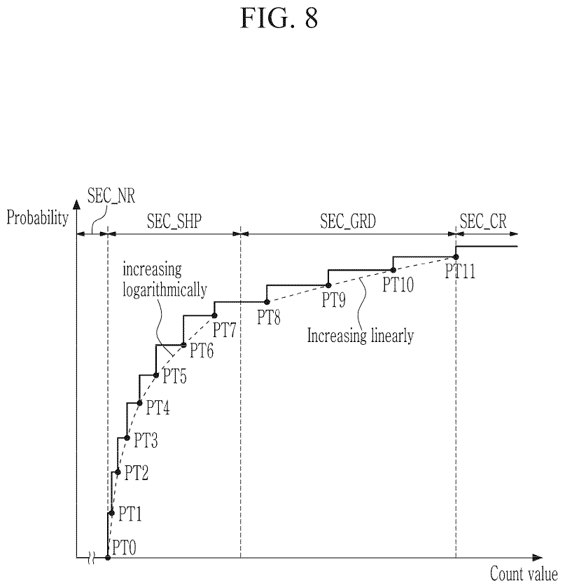

The 0-th to twelfth probabilities P0 to P12 may be integers being 0 or more and 1 or less, and may form an increasing sequence. For example, P1 may be a real number greater than or equal to P0, and P2 may be a real number greater than or equal to P1. Therefore, according to some example embodiments of the inventive concepts, as the count value CV becomes larger, each of the first to n-th row hammering protection circuits 171_1 to 171_n may issue the row refresh command CMD_RREF with higher probability. In other words, as the count value CV increases, the probability corresponding to the corresponding count value CV may increase stepwise. The relationship of the count value CV and the probability to issue the row refresh command CMD_RREF will be hereinafter described in more detail with reference to FIG. 8.

According to some example embodiments, the count ranges, which are respectively corresponding to the 0-th to twelfth row hammering threat levels L0 to L12, may be divided into a plurality of sections. For example, a count range corresponding to the 0-th row hammering threat level L0 may be included in a no-response section SEC_NR; count ranges corresponding to the first to seventh row hammering threat levels L1 to L7 may be included in a sharp increase section SEC_SHP; count ranges corresponding to the eighth to eleventh row hammering threat levels L8 to L11 may be included in a gradual increase section SEC_GRD; a count range corresponding to the twelfth row hammering threat level L12 may be included a certain response section SEC_CR.

When the count range corresponding to the count value CV is included in the no-response section SEC_NR, the second row hammering protection circuit 171_2 may not issue the row refresh command CMD_RREF within the first bank refresh period P1_REF. For example, the 0-th probability P0 may be 0.

When the count range corresponding to the count value CV is included in the sharp increase section SEC_SHP, as the count value CV increases, the probability for the second row hammering protection circuit 171_2 to issue the row refresh command CMD_RREF within the first bank refresh period P1_REF may rapidly increase.

In some example embodiments, the probabilities (e.g., the first to seventh probabilities P1 to P7) corresponding to count ranges included in the sharp increase section SEC_SHP may be logarithmic with respect to upper limit values (e.g., B1 to B7) of the count ranges included in the sharp increase section SEC_SHP.

When the count range corresponding to the count value CV is included in the gradual increase section SEC_GRD, as the count value CV increases, the probability for the second row hammering protection circuit 171_2 to issue the row refresh command CMD_RREF within the first bank refresh period P1_REF may gradually (e.g., gently) increase.

In some example embodiments, the probabilities (e.g., the eighth to eleventh probabilities P8 to P11) corresponding to the count ranges included in the gradual increase section SEC_GRD may be linear with respect to upper limit values (e.g., B8 to B11) of the count ranges included in the gradual increase section SEC_GRD.

When the count range corresponding to the count value CV is included in the certain response section SEC_CR, the second row hammering protection circuit 171_2 may definitively issue the row refresh command CMD_RREF within the first bank refresh period P1_REF. For example, a twelfth probability P12 may be 1.

For a more concise description, FIG. 7 illustrates, as an example, some example embodiments in which the count ranges corresponding to the 0-th to twelfth row hammering threat levels L0 to L12 are split into 4 sections, but example embodiments are not limited thereto.

In some example embodiments, B0 to B11 and the 0-th to twelfth probabilities P0 to P12 may be generated based on 4-th Runge-kutta algorithm. However, example embodiments are not limited to a specific method of determining B0 to B11 and the 0-th to twelfth probabilities P0 to P12.

In some example embodiments, the interval of B0 to B11 may form an increasing sequence. For example, the interval between Bi and Bi+1 may be greater than or equal to the interval between limit values Bi and Bi−1 (here, ‘i’ is an integer greater than or equal to 1). In this case, the size of the count ranges included in the gradual increase section SEC_GRD may be greater than or equal to the size of the count ranges included in the sharp increase section SEC_SHP. However, example embodiments are not limited thereto.

In some example embodiments, the differences between the 0-th to twelfth probabilities P0 to P12 may form a decreasing sequence. For example, the interval between the i-th probability Pi and the i+1-th probability Pi+1 may be smaller than or equal to the interval between the i-th probability Pi and the i−1-th probability Pi−1 (here, ‘i’ is an integer greater than or equal to 1). However, example embodiments are not limited thereto.

FIG. 8 is a graph showing a relationship of the probability of issuing the row refresh command with respect to the count value. The horizontal axis of FIG. 8 may represent the size of the count value CV, and the vertical axis may represent the probability for the command issuing circuit CIC to issue the row refresh command CMD_RREF.

Referring to FIG. 1 to FIG. 8, the 0-th to eleventh probabilities P0 to P11 of the global probability table GPT and upper limit values (e.g., B0 to B11) of count ranges corresponding thereto may be illustrated as dots in FIG. 8. For example, the upper limit value (e.g., B0) and the 0-th probability P0 of count range corresponding to the 0-th row hammering threat level L0 may be illustrated as a 0-th point PT0; the upper limit value (e.g., B1) and a first probability P1 of count range corresponding to the first row hammering threat level L1 may be illustrated as a first point PT1. In this way, the upper limit value of the count ranges corresponding to the 0-th to eleventh row hammering threat levels L0 to L11, and the 0-th to eleventh probabilities P0 to P11 may be illustrated as 0-th to eleventh points PT0 to PT11, respectively.

When the count value CV corresponds to the no-response section SEC_NR, the probability for the second row hammering protection circuit 171_2 to issue the row refresh command CMD_RREF may be 0.

That is, even if the count value CV increases as the activation with respect to a specific wordline is generated from the memory controller 10 for a normal operation of the memory device 100, the row hammering protector 170 may not perform the additional refresh operation with respect thereto. For example, even if the memory device 100 activates wordlines adjacent to the second wordline WL2 for a normal operation and thereby the second count value CV2 increases, the second row hammering protection circuit 171_2 may not issue the row refresh command CMD_RREF with respect to the second wordline WL2. That is, according to some example embodiments of the inventive concepts, the operation delay and power consumption of the memory device 100, which may occur as the row hammering protector 170 unnecessarily performs the additional refresh operation, may be, reduced or, minimized.

When the count value CV corresponds to the sharp increase section SEC_SHP, the probability for the second row hammering protection circuit 171_2 to issue the row refresh command CMD_RREF may rapidly increase according to the count value CV. Hereinafter, for a more concise description, it is assumed that the 0-th to seventh points PT0 to PT7 included in the sharp increase section SEC_SHP is illustrated with one log graph. However, example embodiments are not limited thereto. For example, the 0-th to seventh points PT0 to PT7 may be illustrated by any type of function graph, such as a polynomial function, a logarithmic function, an exponential function, and/or the like.

That is, according to some example embodiments of the inventive concepts, since the probability for the second row hammering protection circuit 171_2 to issue the row refresh command CMD_RREF sharply increases according to the count value CV in the sharp increase section SEC_SHP, the second row hammering protection circuit 171_2 may operate more sensitively for the possibility that the adjacent wordline activation for the second wordline WL2 has been performed due to the row hammering attack. Therefore, according to some example embodiments of the inventive concepts, the probability for the second row hammering protection circuit 171_2 to defend against the row hammering attack may be increased or maximized.

When the count value CV corresponds to the gradual increase section SEC_GRD, the probability for the second row hammering protection circuit 171_2 to issue the row refresh command CMD_RREF may gradually increase according to the count value CV. Hereinafter, for a more concise description, it is assumed that the eighth to eleventh points PT8 to PT11 included in the gradual increase section SEC_GRD are illustrated in one straight line graph. However, example embodiments are not limited thereto. For example, the eighth to eleventh points PT8 to PT11 may be illustrated by any type of function graph, such as a polynomial function, a logarithmic function, an exponential function, and/or the like.

That is, according to some example embodiments of the inventive concepts, since the probability for the second row hammering protection circuit 171_2 to issue the row refresh command CMD_RREF gradually increases according to the count value CV in the gradual increase section SEC_GRD, the second row hammering protection circuit 171_2 may operate more finely for the possibility that the adjacent wordline activation with respect to the second wordline WL2 has been performed due to the row hammering attack. Therefore, according to some example embodiments of the inventive concepts, when the memory device 100 normally operates, the probability that unnecessary additional refresh operations with respect to the second wordline WL2 is to be performed may be reduced or minimized. In other words, according to some example embodiments of the inventive concepts, a ‘false-positive rate’ of the second row hammering protection circuit 171_2 may be reduced or minimized.

In some example embodiments, slopes between points included in the gradual increase section SEC_GRD may be the same. For example, the slope between the eighth point PT8 and the ninth point PT9 may be the same as the slope between the tenth point PT10 and the eleventh point PT11.

In some example embodiments, the variation ratio of the probability with respect to the count value CV in the sharp increase section SEC_SHP may be greater than the variation ratio of the probability with respect to the count value CV in the gradual increase section SEC_GRD. For example, a slope between the 0-th point PT0 and the seventh point PT7 may be greater than a slope between the eighth point PT8 and the eleventh point PT11.

When the count value CV corresponds to the certain response section SEC_CR, the probability for the second row hammering protection circuit 171_2 to issue the row refresh command CMD_RREF may be 1. That is, when it is certain that the memory controller 10 is performing the row hammering attack, the second row hammering protection circuit 171_2 may issue the row refresh command CMD_RREF with respect to the second wordline WL2. Therefore, according to some example embodiments of the inventive concepts, when it is certain that the memory controller 10 is performing the row hammering attack, the second row hammering protection circuit 171_2 may reduce or prevent damage of data stored in the second wordline WL2 by performing the additional refresh operation with respect to the second wordline WL2.

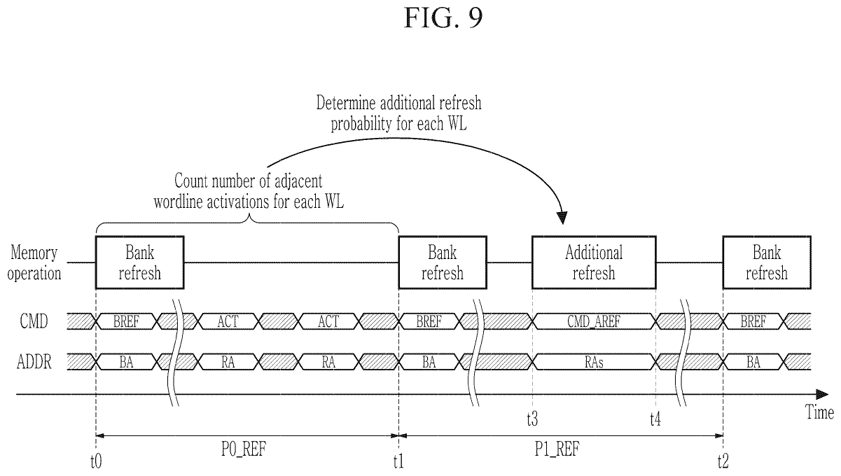

FIG. 9 is a timing diagram showing the operation of a memory device according to some example embodiments. Referring to FIG. 1 to FIG. 9, the memory device 100 may receive a bank refresh command BREF together with a bank address BA at a 0-th time point t0, the first time point t1, and/or the second time point t2. The memory device 100 may perform the bank refresh operation at the 0-th time point to, the first time point t1, and/or the second time point t2 in response to the bank refresh command BREF.

Within the 0-th bank refresh period P0_REF between the 0-th time point to and the first time point t1, the memory device 100 may receive a plurality of activation commands ACT. In this case, the row hammering protector 170 may count the number of adjacent wordline activations with respect to each, or one or more, of the plurality of wordlines WL, based on a row address RA received together with the plurality of activation commands ACT. For example, the first to n-th row hammering protection circuits 171_1 to 171_n may respectively generate the first to n-th count values CV1 to CVn by counting the number of times the activation commands ACT for adjacent wordlines with respect to the first to n-th wordlines WL1 to WLn, respectively. For a more specific example, each, or one or more, of the count circuit CNT of the first to n-th row hammering protection circuits 171_1 to 171_n may count the number of times the activation command ACT is received together with the row address RA for wordlines adjacent to the corresponding wordline.

After the first time point t1, each, or one or more, of the probability determination circuit PDC of the first to n-th row hammering protection circuits 171_1 to 171_n may identify the probability corresponding to the count value CV based on the global probability table GPT. For example, from among the plurality of probabilities included in the global probability table GPT, each, or one or more, of the probability determination circuit PDC of the first to n-th row hammering protection circuits 171_1 to 171_n may identify a probability corresponding to the count range including the count value CV. Each, or one or more, of the probability determination circuit PDC of the first to n-th row hammering protection circuits 171_1 to 171_n may store the identified probability in probability buffer circuit PBC. That is, probability buffer circuits PBC of the first to n-th row hammering protection circuits 171_1 to 171_n may store an additional refresh probability for the first to n-th wordlines WL1 to WLn, respectively.

Within the first bank refresh period P1_REF between the first time point t1 and the second time point t2, the row hammering protector 170 may issue the additional refresh command CMD_AREF. For example, the row hammering protector 170 may provide the additional refresh command CMD_AREF to the control logic circuit 160 at a third time point t3 within the first bank refresh period P1_REF. In this case, the memory device 100 may perform the additional refresh operation between the third time point t3 and a fourth time point t4 in response to the additional refresh command CMD_AREF.

More specifically, the timer 173 may generate the trigger signal TS at the third time point t3 at which a predetermined, or alternately given, time length has elapsed from the first time point t1. In response to the trigger signal TS, the command issuing circuits CIC of each, or one or more, of the first to n-th row hammering protection circuits 171_1 to 171_n may issue the row refresh command CMD_RREF according to the probability stored in the probability buffer circuit PBC included therein. The additional refresh circuit 174 may generate the additional refresh command CMD_AREF, based on the one or more row refresh commands CMD_RREF provided from the plurality of row hammering protection circuits 171. The memory device 100 may perform the additional refresh operation based on the additional refresh command CMD_AREF.

That is, according to some example embodiments of the inventive concepts, within the first bank refresh period P1_REF, an additional refresh with respect to the wordline with a large number of adjacent wordline activations during the 0-th bank refresh period P0_REF may be performed with high probability.

FIG. 10 and FIG. 11 are timing diagrams showing the partial time period of FIG. 9 in more detail. Hereinafter, some example embodiments in which the memory device 100 performs the additional refresh operation in a target row refresh (TRR) mode will be described with reference to FIG. 10; and some example embodiments in which the memory device 100 performs the additional refresh operation with respect to a plurality of wordlines based on a plurality of row refresh commands CMD_RREF will be described with reference to FIG. 11.

First, referring to FIG. 1 to FIG. 10, the memory device 100 may perform the additional refresh operation between the third time point t3 and the fourth time point t4 in response to the additional refresh command CMD_AREF.

A TRR mode enter command TRRE and/or the one or more row refresh commands CMD_RREF may be included in the command sequence of the additional refresh command CMD_AREF. Hereinafter, for a more concise description, some example embodiments in which a first row refresh command CMD_RREFa and/or a second row refresh command CMD_RREFb is included in the command sequence of the additional refresh command CMD_AREF will be described in detail, as an example. However, example embodiments are not limited to the number of row refresh commands included in the command sequence of the additional refresh command CMD_AREF.

The additional refresh circuit 174 may issue the TRR mode enter command TRRE together with the bank address BA corresponding to the memory cell array 120 at the third time point t3. In this case, the memory device 100 may enter the TRR mode with respect to the bank address BA.

In some example embodiments, the TRR mode enter command TRRE may be implemented as a mode register write (MRW) command. However, example embodiments are not limited thereto.

The additional refresh circuit 174 may issue the first row refresh command CMD_RREFa at a fifth time point t5 after the third time point t3. The first row refresh command CMD_RREFa may include the activation command ACT with respect to a first victim wordline WL_VCTa and/or a precharge command PRE with respect to the memory cell array 120. In this case, the memory device 100 may refresh memory cells connected to the first victim wordline WL_VCTa based on the activation command ACT with respect to the first victim wordline WL_VCTa.

In some example embodiments, the additional refresh circuit 174 may issue a row address RA_VCTa for the first victim wordline WL_VCTa together with the activation command ACT for the first victim wordline WL_VCTa. The additional refresh circuit 174 may issue the bank address BA corresponding to the memory cell array 120 together with the precharge command PRE for the memory cell array 120.

Thereafter, the additional refresh circuit 174 may issue the second row refresh command CMD_RREFb at a sixth time point t6 after the fifth time point t5. The second row refresh command CMD_RREFb may include the activation command ACT for a second victim wordline WL_VCTb and/or the precharge command PRE for the memory cell array 120. In this case, the memory device 100 may refresh memory cells connected to the second victim wordline WL_VCTb based on the activation command ACT for the second victim wordline WL_VCTb.

In this way, the memory device 100 may enter the TRR mode, and may sequentially perform the additional refresh operation for a plurality of wordlines.

In some example embodiments, the first victim wordline WL_VCTa and the second victim wordline WL_VCTb may be different wordlines.

In some example embodiments, the first row refresh command CMD_RREFa and the second row refresh command CMD_RREFb may correspond to row refresh commands issued from different two among the first to n-th row hammering protection circuits 171_1 to 171_n, respectively.

The additional refresh circuit 174 may issue all, or one or more, the row refresh commands CMD_RREF provided from the first to n-th row hammering protection circuits 171_1 to 171_n, and then issue a TRR mode termination command TRRX. In this case, the memory device 100 may enter an idle state from the TRR mode.

For a more concise description, FIG. 9 illustrates, as an example, some example embodiments in which the additional refresh circuit 174 issues the TRR mode termination command TRRX, but example embodiments are not limited thereto. For example, the memory device 100 may perform the row refresh operations corresponding to the predetermined, or alternately given, number of wordlines and then return to the idle state by itself, and/or may return to the idle state after a predetermined time has elapsed after entering the TRR mode.

Referring to FIG. 1 to FIG. 9, and FIG. 11, the memory device 100 may perform the additional refresh operation between the third time point t3 and the fourth time point t4 in response to the additional refresh command CMD_AREF. Hereinafter, differences from some example embodiments described with reference to FIG. 10 will be focused on.

The one or more row refresh commands CMD_RREF may be included in the command sequence of the additional refresh command CMD_AREF. For example, the first row refresh command CMD_RREFa and/or the second row refresh command CMD_RREFb may be included in the command sequence of the additional refresh command CMD_AREF. However, example embodiments are not limited to the number of row refresh commands included in the command sequence of the additional refresh command CMD_AREF.

The additional refresh circuit 174 may issue the first row refresh command CMD_RREFa at the third time point t3. The additional refresh circuit 174 may issue the second row refresh command CMD_RREFb at a seventh time point t7 after the third time point t3. That is, the additional refresh circuit 174 may perform the additional refresh operation without entering the TRR mode. Each, or one or more, of the first row refresh command CMD_RREFa and/or the second row refresh command CMD_RREFb may include the activation command CMD and the precharge command PRE.

In some example embodiments, the additional refresh circuit 174 may issue the row address RA_VCTa and/or the bank address BA for the first victim wordline WL_VCTa together with the activation command ACT for the first victim wordline WL_VCTa. The additional refresh circuit 174 may issue a row address RA_VCTb and/or the bank address BA for the second victim wordline WL_VCTb together with the activation command ACT for the second victim wordline WL_VCTb.

FIG. 12 is a timing diagram showing the operation of a memory device according to some example embodiments. Referring to FIG. 1 to FIG. 12, the memory device 100 may perform the bank refresh operation at the first to fourth time points ta to td. Hereinafter, a time period between a first time point ta and a second time point tb may be referred to as a first bank refresh period Pa_REF; a time period between the second time point tb and a third time point tc may be referred to as a second bank refresh period Pb_REF; a time period between the third time point tc and a fourth time point td may be referred to as a third bank refresh period Pc_REF.

The memory device 100 may determine whether to perform the additional refresh operation with respect to each, or one or more, of the plurality of wordlines WL within the first bank refresh period Pa_REF, based on the number of the adjacent wordline activations with respect to each, or one or more, of the plurality of wordlines WL during the first bank refresh period Pa_REF.

The row hammering protector 170 may generate the first to n-th count values CV1 to CVn based on the number of the adjacent wordline activations with respect to each, or one or more, of the plurality of wordlines WL during the first bank refresh period Pa_REF. The second time point tb thereafter, the row hammering protector 170 may determine the additional refresh probability with respect to each, or one or more, of the plurality of wordlines WL based on the first to n-th count values CV1 to CVn. After a predetermined, or alternately given, time has elapsed from the second time point tb, based on the determined probability, the row hammering protector 170 may probabilistically issue additional an refresh command with respect to each, or one or more, of the plurality of wordlines WL.

Similarly, the memory device 100 may determine whether to perform the additional refresh operation with respect to each, or one or more, of the plurality of wordlines WL within the third bank refresh period Pc_REF, based on the number of the adjacent wordline activations with respect to each, or one or more, of the plurality of wordlines WL during the second bank refresh period Pb_REF. The memory device 100 may determine whether to perform the additional refresh operation with respect to each, or one or more, of the plurality of wordlines WL within bank refresh period after the third bank refresh period Pc_REF, based on the number of the adjacent wordline activations with respect to each, or one or more, of the plurality of wordlines WL during the third bank refresh period Pc_REF.

In this way, throughout a plurality of bank refresh periods, based on the number of the adjacent wordline activations with respect to each, or one or more, of the plurality of wordlines WL during the previous bank refresh period, the memory device 100 may probabilistically perform the additional refresh operation with respect to each, or one or more, of the plurality of wordlines WL within the subsequent bank refresh period. In this case, even if the memory device 100 row hammering attacked throughout a plurality of bank refresh periods, the probability of increasing or ensuring integrity of data stored in the memory device 100 may increase.

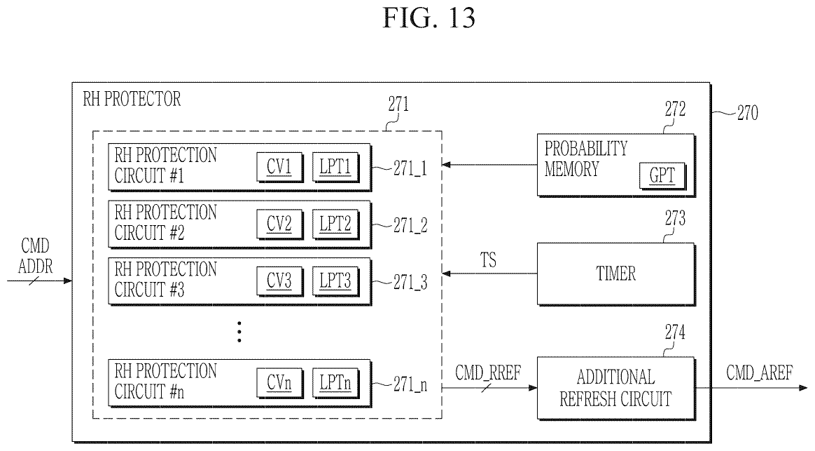

FIG. 13 is a block diagram showing the row hammering protector of FIG. 2 according to some example embodiments in more detail. Referring to FIG. 1 to FIG. 4 and FIG. 13, the row hammering protector 170 of FIG. 2 may be implemented as a row hammering protector 270.

The row hammering protector 270 may include a plurality of row hammering protection circuits 271, a probability memory 272, a timer 273, and/or an additional refresh circuit 274. The configuration and/or operation of the probability memory 272, the timer 273, and/or the additional refresh circuit 274 are similar to what has been described above with reference to FIG. 5, and is not described in further detail.

The plurality of row hammering protection circuits 271 may include first to n-th row hammering protection circuits 271_1 to 271_n.

The first to n-th row hammering protection circuits 271_1 to 271_n may generate the first to n-th count values CV1 to CVn by counting the number of adjacent wordline activations with respect to the first to n-th wordlines WL1 to WLn, respectively.

Each, or one or more, of the first to n-th row hammering protection circuits 271_1 to 271_n may manage a local probability table LPT. For example, the probability determination circuits PDC included in the first to n-th row hammering protection circuits 271_1 to 271_n may manage first to n-th local probability tables LPT1 to LPTn, respectively.

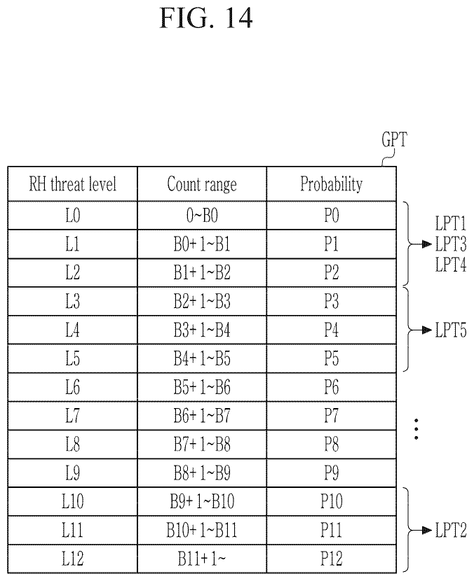

Each, or one of more, of the first to n-th local probability tables LPT1 to LPTn may be a portion of the global probability table GPT. For example, each, or one or more, of the first to n-th local probability tables LPT1 to LPTn may include a portion among the plurality of probabilities included in the global probability table GPT. The configuration of each, or one or more, of the first to n-th local probability tables LPT1 to LPTn will be hereinafter described in more detail with reference to FIG. 14.

In some example embodiments, capacities of the first to n-th local probability tables LPT1 to LPTn may be the same with each other.

In some example embodiments, the plurality of probabilities included in each, or one or more, of the first to n-th local probability tables LPT1 to LPTn may correspond to consecutive count ranges. For example, the plurality of probabilities included in the second local probability table LPT2 may correspond to consecutive row hammering threat levels within the global probability table GPT.

The first to n-th row hammering protection circuits 271_1 to 271_n may respectively identify the probability corresponding to the count value CV among the plurality of probabilities included in the first to n-th local probability tables LPT1 to LPTn. For example, the probability determination circuits PDC included in the second row hammering protection circuit 271_2 may identify the probability corresponding to the second count value CV2 from the second local probability table LPT2.

In response to the trigger signal TS, the first to n-th row hammering protection circuits 271_1 to 271_n may issue row refresh command with respect to the corresponding wordline according to the identified probability. For example, the command issuing circuit CIC included in the second row hammering protection circuit 271_2 may issue the row refresh command CMD_RREF with respect to the second wordline WL2 according to the probability identified by the probability determination circuit PDC.

That is, according to some example embodiments of the inventive concepts, the first to n-th row hammering protection circuits 271_1 to 271_n may determine the probability corresponding to the count value CV based on the local probability table LPT. In this case, the number of times of which the first to n-th row hammering protection circuits 271_1 to 271_n access the probability memory 272 may be reduced or minimized, and accordingly, the operation performance of the memory device 100 may be improved.

FIG. 14 is a drawing showing a relationship of the local probability table and global probability table of FIG. 13 according to some example embodiments. Referring to FIG. 1 to FIG. 4 and FIG. 13 to FIG. 14, each, or one or more, of the first to n-th local probability tables LPT1 to LPTn may be a portion of the global probability table GPT. The sizes of the first to n-th local probability tables LPT1 to LPTn may be the same with each other. Hereinafter, for a more concise description, it is assumed that each of the first to n-th local probability tables LPT1 to LPTn corresponds to three row hammering threat levels. However, example embodiments are not limited thereto.

First local probability table LPT1, third local probability table LPT3, and fourth local probability table LPT4 may correspond to the 0-th to second row hammering threat levels L0 to L2 of the global probability table GPT. Fifth local probability table LPT5 may correspond to the third to fifth row hammering threat levels L3 to L5 of the global probability table GPT. The second local probability table LPT2 may correspond to the tenth to twelfth row hammering threat levels L10 to L12 of the global probability table GPT.

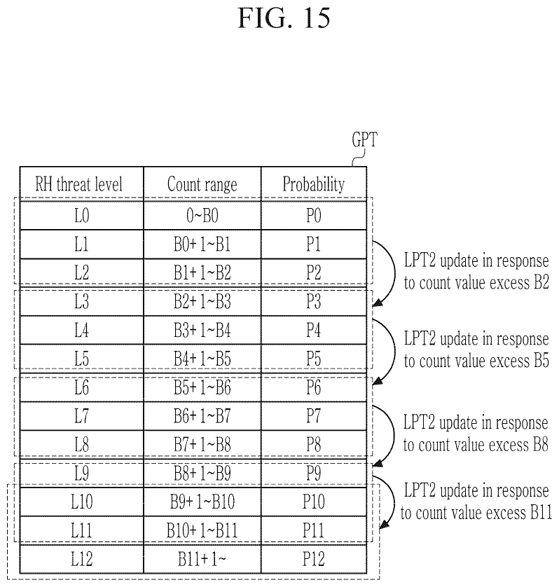

The first to n-th local probability tables LPT1 to LPTn may be updated based on the first to n-th count values CV1 to CVn, respectively. For example, when the second local probability table LPT2 does not include a count range corresponding to the second count value CV2, the second local probability table LPT2 may be updated to include the count range corresponding to the second count value CV2. A method of updating the first to n-th local probability tables LPT1 to LPTn will be hereinafter described in further detail with reference to FIG. 15.

FIG. 15 is a drawing showing a method of updating the local probability table of FIG. 13 according to some example embodiments. Hereinafter, a method of updating the second local probability table LPT2 will be hereinafter described, as an example, with reference to referring to FIG. 1 to FIG. 4 and FIG. 13 to FIG. 15. However, example embodiments are not limited thereto, and the first to n-th local probability tables LPT1 to LPTn may also be updated in a similar manner.

The second local probability table LPT2 may be updated in real-time according to the second count value CV2. For example, during the 0-th bank refresh period P0_REF, as adjacent wordlines with respect to the second wordline WL2 are repeatedly activated, the second count value CV2 may sequentially increase. In this case, the second count value CV2 may become out of the count ranges with respect to the probabilities included in the second local probability table LPT2. In this case, the probability determination circuit PDC of the second row hammering protection circuit 271_2 may update the second local probability table LPT2.

The probability determination circuit PDC of the second row hammering protection circuit 271_2 may update the second local probability table LPT2 in a window sliding scheme. For example, when the second count value CV2 exceeds ‘B2’, the probability determination circuit PDC of the second row hammering protection circuit 271_2 may update the second local probability table LPT2 to correspond to the third to fifth row hammering threat levels L3 to L5 of the global probability table GPT; when the second count value CV2 exceeds ‘B5’, the probability determination circuit PDC of the second row hammering protection circuit 271_2 may update the second local probability table LPT2 to correspond to the sixth to eighth row hammering threat levels L6 to L8 of the global probability table GPT; and when the second count value CV2 exceeds ‘B8’, the probability determination circuit PDC of the second row hammering protection circuit 271_2 may update the second local probability table LPT2 to correspond to the ninth to eleventh row hammering threat levels L9 to L11 of the global probability table GPT. That is, whenever the second count value CV2 becomes out of the count range corresponding to the second local probability table LPT2, the probability determination circuit PDC of the second row hammering protection circuit 271_2 may update the second local probability table LPT2 based on subsequent three (e.g., the quantity corresponding to the size of the second local probability table LPT2) row hammering threat levels of the global probability table GPT.

According to some example embodiments, when the second count value CV2 exceeds ‘B11’, the probability determination circuit PDC of the second row hammering protection circuit 271_2 may update the second local probability table LPT2 to correspond to top three (e.g., the quantity corresponding to the size of the second local probability table LPT2) row hammering threat levels of the global probability table GPT. For example, the probability determination circuit PDC of the second row hammering protection circuit 271_2 may update the second local probability table LPT2 to correspond to the tenth to twelfth row hammering threat levels L10 to L12 of the global probability table GPT.

Therefore, according to some example embodiments of the inventive concepts, the capacity of the mapping table stored in each, or one or more, of the first to n-th row hammering protection circuits 271_1 to 271_n may be reduced or minimized. For example, the size of the first to n-th local probability tables LPT1 to LPTn may be smaller than the global probability table GPT, and accordingly, the row hammering protector 270 may be implemented in a further smaller size.

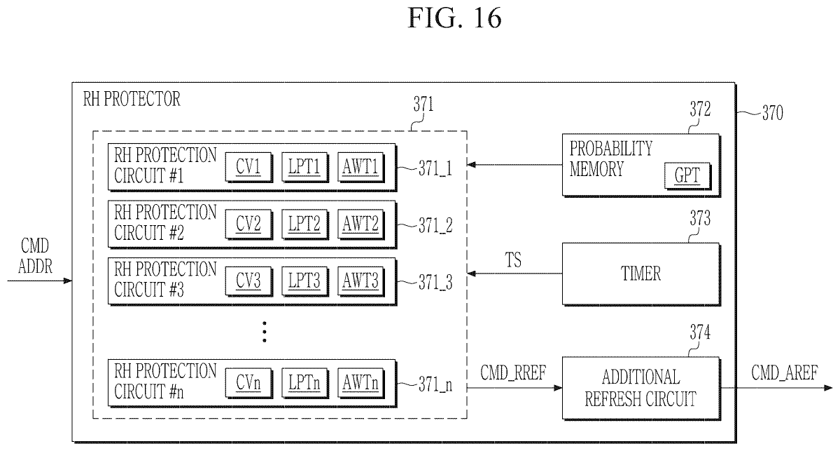

FIG. 16 is a block diagram showing the row hammering protector of FIG. 2 according to some example embodiments in more detail. Referring to FIG. 1 to FIG. 4 and FIG. 13, the row hammering protector 170 of FIG. 2 may be implemented as a row hammering protector 370.

The row hammering protector 370 may include a plurality of row hammering protection circuits 371, a probability memory 372, a timer 373, and/or an additional refresh circuit 374. The configuration and operation of the probability memory 372, the timer 373, and the additional refresh circuit 374 are similar to what has been described above with reference to FIG. 5, and/or is not described in further detail.

The plurality of row hammering protection circuits 371 may include first to n-th row hammering protection circuits 371_1 to 371_n. Hereinafter, differences between the first to n-th row hammering protection circuits 371_1 to 371_n and the first to n-th row hammering protection circuits 271_1 to 271_n will be focused on.

The first to n-th row hammering protection circuits 371_1 to 371_n may generate the first to n-th count values CV1 to CVn by counting the number of adjacent wordline activations with respect to the first to n-th wordlines WL1 to WLn, respectively.

The first to n-th row hammering protection circuits 371_1 to 371_n may manage the first to n-th local probability tables LPT1 to LPTn.

Each, or one or more, of the first to n-th row hammering protection circuits 371_1-371_n may manage an adjustment weight table AWT. For example, the probability determination circuits PDC included in the first to n-th row hammering protection circuits 371_1-371_n may manage first to n-th adjustment weight tables AWT1 to AWTn, respectively.

Each, or one or more, of the first to n-th adjustment weight tables AWT1 to AWTn may include a plurality of adjustment weights corresponding to a plurality of row hammering threat levels of the global probability table GPT, respectively. For example, each, or one or more, of the first to n-th adjustment weight tables AWT1 to AWTn may include a plurality of adjustment weights corresponding to the 0-th to twelfth row hammering threat levels L0 to L12, respectively.

The first to n-th row hammering protection circuits 371_1-371_n may adjust count ranges of the first to n-th local probability tables LPT1 to LPTn based on each, or one or more, the first to n-th adjustment weight tables AWT1 to AWTn. For example, a second row hammering protection circuit 371_2 may adjust the count ranges of the second local probability table LPT2 based on the second adjustment weight table AWT2.

That is, each, or one or more, of the first to n-th row hammering protection circuits 371_1-371_n may individually manage the adjustment weight table AWT, and accordingly, the first to n-th local probability tables LPT1 to LPTn may be individually adjusted. Therefore, the additional refresh probability for each, or one or more, of the first to n-th wordlines WL1 to WLn may be determined based on a different local count table. In this case, according to the characteristics of data stored in the memory cells connected to each, or one or more, of the first to n-th wordlines WL1 to WLn, the additional refresh probability with respect to the first to n-th wordlines WL1 to WLn may be individually determined. As a result, according to some example embodiments of the inventive concepts, since the additional refresh probability with respect to each, or one or more, of the first to n-th wordlines WL1 to WLn may be optimally determined, the possibility of unnecessarily performing the additional refresh operation may be reduced or minimized, and also the possibility of damage to the data stored in the memory device 100 due to the additional refresh operation not being performed may be reduced or minimized.

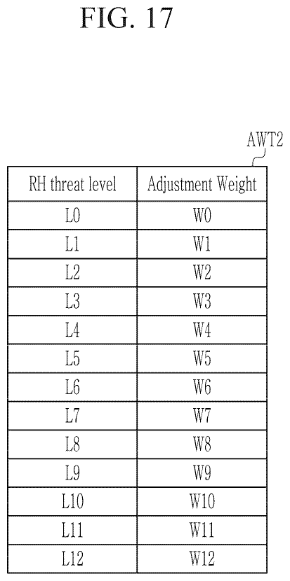

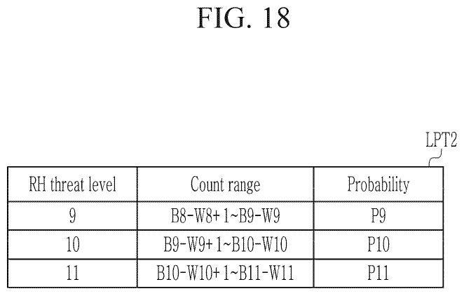

FIG. 17 and FIG. 18 are drawings showing the relationship of the adjustment weight table and local probability table of FIG. 16 according to some example embodiments. Hereinafter, the adjustment weight table AWT will be described with reference to FIG. 17, and the local probability table LPT adjusted based on the adjustment weight table AWT will be described with reference to FIG. 18. However, hereinafter, for a more concise description, the relationship between the second adjustment weight table AWT2 and the second local probability table LPT2 will be described in detail, as an example. However, example embodiments are not limited thereto, and the relationships between the first to n-th adjustment weight tables AWT1 to AWTn and the first to n-th local probability tables LPT1 to LPTn may also be implemented in a similar manner.

Referring to FIG. 1 to FIG. 4 and FIG. 16 to FIG. 17, the second adjustment weight table AWT2 may include 0-th to twelfth adjustment weights W0 to W12. Each, or one or more, of the 0-th to twelfth adjustment weights W0 to W12 may correspond to the 0-th to twelfth row hammering threat levels L0 to L12, respectively of the global probability table GPT. Each, or one or more, of the 0-th to twelfth adjustment weights W0 to W12 may be used for adjustment of the upper limit value of the count range with respect to corresponding row hammering threat level.

For example, referring also to FIG. 18, the second local probability table LPT2 may correspond to the ninth to eleventh row hammering threat levels L9 to L11 of the global probability table GPT. In this case, the ninth to eleventh adjustment weights W9 to W11 may be used for adjustment of the upper limit value of the count ranges within the second local probability table LPT2.

For example, the upper limit value of the count range corresponding to a ninth row hammering threat level L9 may be adjusted based on a ninth adjustment weight W9. For example, the upper limit value of the count range corresponding to the ninth row hammering threat level L9 may be determined as a value obtained by subtracting the ninth adjustment weight W9 from B9. Similarly, the upper limit value of the count range corresponding to a tenth row hammering threat level L10 may be adjusted based on a tenth adjustment weight W10; and the upper limit value of the count range corresponding to the eleventh row hammering threat level L11 may be adjusted based on an eleventh adjustment weight W11.

In some example embodiments, the lower limit value of count range of the second local probability table LPT2 may be adjusted based on the upper limit value of the preceding count range. For example, the lower limit value of the count range corresponding to the tenth row hammering threat level L10 may be adjusted to be greater than the upper limit value of the count range corresponding to the ninth row hammering threat level L9 by 1. Similarly, the lower limit value of the count range corresponding to the ninth row hammering threat level L9 may be adjusted to be greater by 1 than the upper limit value of the count range corresponding to an eighth row hammering threat level L8 before the second local probability table LPT2 is updated in the method described above with reference to FIG. 14.

That is, according to some example embodiments of the inventive concepts, as the adjustment weight increases, the additional refresh operation may be performed with respect to the wordline corresponding to a further lower count value with gradually higher probability.

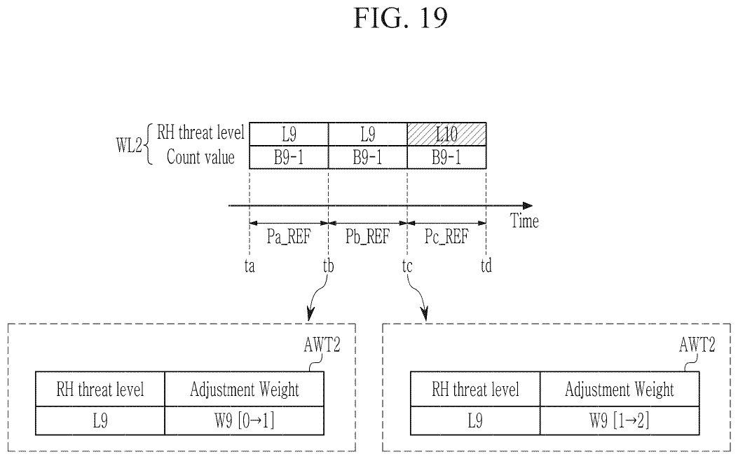

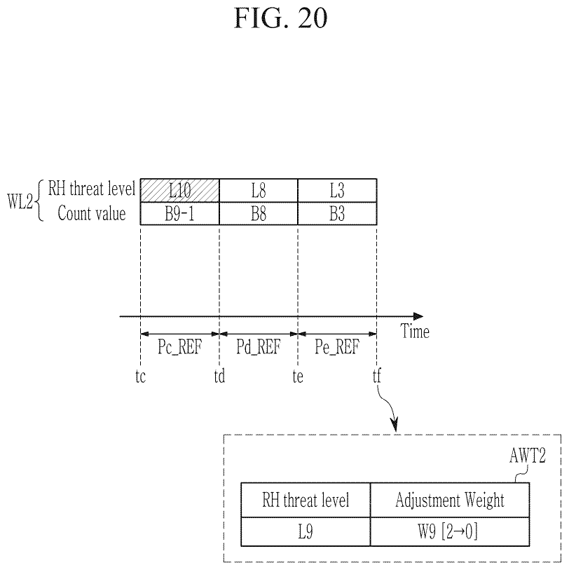

FIG. 19 and FIG. 20 are timing diagrams showing the operation of the memory device according to some example embodiments of FIG. 18. First, referring to FIG. 1 to FIG. 4 and FIG. 16 to FIG. 19, the memory device 100 may perform the bank refresh operation at the first to fourth time points ta to td. A time period between the first time point ta and the second time point tb may be referred to as the first bank refresh period Pa_REF; a time period between the second time point tb and the third time point tc may be referred to as the second bank refresh period Pb_REF; and a time period between the third time point tc and the fourth time point td may be referred to as the third bank refresh period Pc_REF. Hereinafter, for brevity of description, it is assumed that the 0-th to twelfth weights W0 to W12 included in the second adjustment weight table AWT2 at the first time point ta is 0. However, example embodiments are not limited thereto.

When the bank refresh is performed (e.g., at the second time point tb, or the like), the probability determination circuit PDC may update the second adjustment weight table AWT2 based on the second count value CV2 of the preceding bank refresh period. Hereinafter, for brevity of description, some example embodiments in which the probability determination circuit PDC updates the second adjustment weight table AWT2 whenever the refresh is performed is described as an example, but example embodiments are not limited thereto. For example, whenever the bank refresh is performed by the predetermined, or alternately given number of times, the probability determination circuit PDC may also be configured to update the second adjustment weight table AWT2.

During the first bank refresh period Pa_REF, the second count value CV2 may be B9-1. In this case, the second count value CV2 may be included in a count range corresponding to the ninth row hammering threat level L9 of the second local probability table LPT2. Therefore, during the second bank refresh period Pb_REF, the probability determination circuit PDC may perform the additional refresh operation based on a ninth probability P9 corresponding to the ninth row hammering threat level L9.

For example, the probability determination circuit PDC may update the adjustment weight corresponding to the count range in which the second count value CV2 is included. For example, at the second time point tb, the ninth adjustment weight W9 included in the second adjustment weight table AWT2 may be increased from 0 to 1. Accordingly, the upper limit value of the count range corresponding to the ninth row hammering threat level L9 of the second local probability table LPT2 may decrease from B9 to B9-1.

Accordingly to some example embodiments, during the second bank refresh period Pb_REF, the second count value CV2 may be B9-1. In this case, the second count value CV2 may be included in count range corresponding to the ninth row hammering threat level L9 of the second local probability table LPT2. Therefore, during the third bank refresh period Pc_REF, the probability determination circuit PDC may perform the additional refresh operation based on the ninth probability P9 corresponding to the ninth row hammering threat level L9. At the third time point tc, the probability determination circuit PDC may increase the ninth adjustment weight W9 included in the second adjustment weight table AWT2 from 1 to 2. Accordingly, the upper limit value of the count range corresponding to the ninth row hammering threat level L9 of the second local probability table LPT2 may decrease from B9-1 to B9-2.

Thereafter, during the third bank refresh period Pc_REF, the second count value CV2 may be B9-1. The second count value CV2 may not be included in the count range corresponding to the ninth row hammering threat level L9 of the second local probability table LPT2, and may be included in the count range corresponding to the tenth row hammering threat level L10. Therefore, the fourth time point td thereafter, the probability determination circuit PDC may perform the additional refresh operation based on a tenth probability P10 corresponding to the tenth row hammering threat level L10.

That is, according to some example embodiments of the inventive concepts, even if adjacent wordline activations with respect to a specific wordline are generated by uniform number throughout a plurality of bank refresh periods, the additional refresh operation may be performed with gradually higher probability as the adjustment weight increases. In this case, even if the memory device 100 is under the row hammering attack for a long time, the additional refresh operation may be performed with gradually higher probability, and accordingly, the stability of data stored in the memory device 100 may be increased or ensured.

In some example embodiments, at the fourth time point td, the probability determination circuit PDC may increase the tenth adjustment weight W10 included in the second adjustment weight table AWT2 from 2 to 3. Accordingly, the upper limit value of the count range corresponding to the ninth row hammering threat level L9 of the second local probability table LPT2 may decrease from B9-2 to B9-3.

Referring further to FIG. 20, the memory device 100 may perform the bank refresh operation at the third to sixth time points tc to tf. The time period between the third time point tc and the fourth time point td may be referred to as the third bank refresh period Pc_REF; a time period between the fourth time point td and a fifth time point the may be referred to as a fourth bank refresh period Pd_REF; and a time period between the fifth time point the and a sixth time point tf may be referred to as a fifth bank refresh period Pe_REF.

During a plurality of bank refresh periods after the fourth time point td, the second count value CV2 may not be included in the count range corresponding to the tenth row hammering threat level L10 of the second local probability table LPT2. For example, during the fourth bank refresh period Pd_REF, the second count value CV2 may be B8, and the second count value CV2 may correspond to the eighth row hammering threat level L8. During the fifth bank refresh period Pe_REF, the second count value CV2 may be B3, and the second count value CV2 may correspond to a third row hammering threat level L3. In this case, the probability determination circuit PDC may decrease the adjustment weight that has not been used after the fourth time point td. For example, the probability determination circuit PDC may decrease the ninth weight W9 from 2 to 0.

For example, according to some example embodiments of FIG. 20, the phenomenon that the additional refresh operation is excessively performed as the adjustment weight value excessively increases may be reduced or prevented.

For a more concise description, FIG. 20 illustrates some example embodiments in which the probability determination circuit PDC initializes the adjustment weight that has not been used for two bank refresh periods, but example embodiments are not limited thereto. For example, the probability determination circuit PDC may be configured to decrease the adjustment weight that has not been used for any number of bank refresh periods to any size.

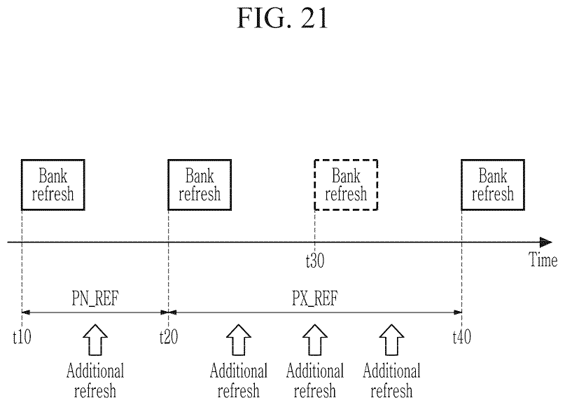

FIG. 21 is a timing diagram showing the operation of the row hammering protection circuit of FIG. 2 according to some example embodiments. Referring to FIG. 1 to FIG. 21, the memory device 100 may perform the bank refresh operation with a predetermined, or alternately given time interval. For example, the memory device 100 may perform the bank refresh operation at a tenth time point t10, a twentieth time point t20, a thirtieth time point t30, and/or a fortieth time point t40 in response to the control of the memory controller 10. In this case, time intervals between the tenth time point t10, the twentieth time point t20, the thirtieth time point t30, and the fortieth time point t40 may be the same with each other.

Meanwhile, in order to secure the operation flexibility of the memory system MS, the memory device 100 may omit the bank refresh operation by a predetermined, or alternately given, number of times. For example, the memory controller 10 may not issue the bank refresh command at the thirtieth time point t30, and/or at the thirtieth time point t30, the memory device 100 may not perform the bank refresh operation. That is, compared to the length of the bank refresh period between the tenth time point t10 and the twentieth time point t20, the length of the bank refresh period between the twentieth time point t20 and the fortieth time point t40 may be longer.

Hereinafter, for a more concise description, the bank refresh period when the bank refresh is performed at a regular interval (e.g., between the tenth time point t10 and the twentieth time point t20) may be referred to as a normal bank refresh period PN_REF, and the bank refresh period when a partial bank refresh is omitted (e.g., between the twentieth time point t20 and the fortieth time point t40) may be referred to as an extended bank refresh period PX_REF.

The number of adjacent wordline activations of each, or one or more, of the plurality of wordlines during the extended bank refresh period PX_REF may be higher than the number of adjacent wordline activations of each, or one or more, of the plurality of wordlines during the normal bank refresh period PN_REF. In this case, the possibility of damage to the data of the memory device 100 due to the row hammering attack during the extended bank refresh period PX_REF may be relatively high.

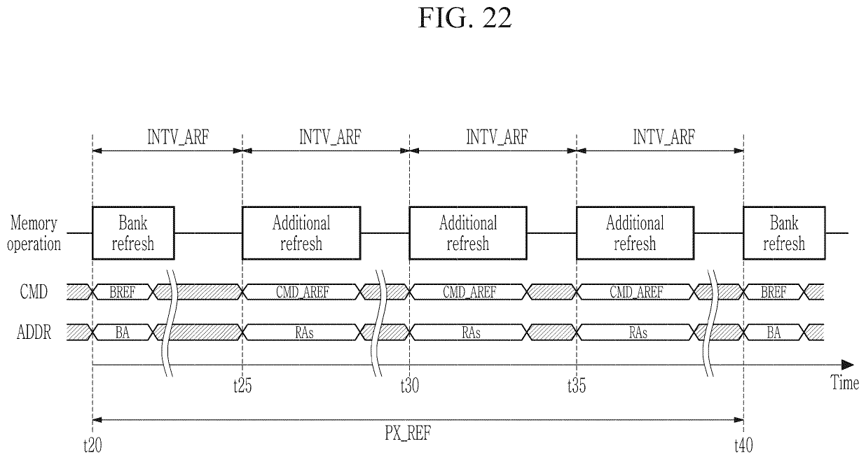

Accordingly, the memory device 100 may perform the additional refresh operation according to some example embodiments, more in the extended bank refresh period PX_REF than in the normal bank refresh period PN_REF. For example, the memory device 100 may perform the additional refresh operation once within the normal bank refresh period PN_REF, and may perform it multiple times within the extended bank refresh period PX_REF. For example, the memory device 100 may perform the additional refresh operation once based on the trigger signal TS issued after a predetermined, or alternately given, time length has elapsed from the tenth time point t10. Similarly, the memory device 100 may perform the additional refresh operation multiple times (e.g., 3 times) based on the trigger signal TS repeatedly issued whenever a predetermined time length elapses from the twentieth time point t20. The method of performing the additional refresh operation within the extended bank refresh period PX_REF will be hereinafter described in further detail with reference to FIG. 22.

FIG. 22 is a timing diagram showing the operation of the memory device during the extended bank refresh period of FIG. 21 in more detail. Hereinafter, the operation of the memory device between the twentieth time point t20 to the fortieth time point t40 of FIG. 21 will be described in detail with reference to FIG. 1 to FIG. 22, as an example.

At the twentieth time point t20, the memory device 100 may receive the bank refresh command BREF. The memory device 100 may perform the bank refresh operation at the twentieth time point t20 in response to the bank refresh command BREF.

Whenever an additional refresh interval INTV_AFR elapses from the twentieth time point t20, the memory device 100 may perform the additional refresh operation. For example, as described above with reference to FIG. 9, the row hammering protector 170 may issue the additional refresh command CMD_AREF. In this case, the memory device 100 may perform the additional refresh operation in response to the additional refresh command CMD_AREF.

In some example embodiments, a length of the additional refresh interval INTV_AFR may be predetermined, or alternately given. Hereinafter, for a more concise description, some example embodiments in which the length of the additional refresh interval INTV_AFR is a half of the normal bank refresh period PN_REF will be described in detail, as an example. However, example embodiments are not limited thereto, and the length of the additional refresh interval INTV_AFR may be determined regardless of the normal bank refresh period PN_REF.

At a twenty-fifth time point t25 at which the additional refresh interval INTV_AFR has elapsed from the twentieth time point t20, the memory device 100 may perform the additional refresh operation. At the thirtieth time point t30 at which the additional refresh interval INTV_AFR has elapsed from the twentieth time point t25, the memory device 100 may perform the additional refresh operation. At a thirty-fifth time point t35 at which the additional refresh interval INTV_AFR has elapsed from the thirtieth time point t30, the memory device 100 may perform the additional refresh operation. For example, at the twenty-fifth time point t25, the thirtieth time point t30, and/or the thirty-fifth time point t35, the row hammering protector 170 may issue the additional refresh command CMD_AREF and the row addresses corresponding thereto.

In some example embodiments, the row addresses issued from the row hammering protector 170 at the twenty-fifth time point t25, the thirtieth time point t30, and the thirty-fifth time point t35 may be the same as or different from each other.

In some example embodiments, at the twenty-fifth time point t25, the thirtieth time point t30, and/or the thirty-fifth time point t35, the row hammering protector 170 may issue the additional refresh command CMD_AREF and/or the row addresses corresponding thereto based on the same probabilities. For example, the row hammering protector 170 may determine the additional refresh the probability of the twenty-fifth time point t25, the thirtieth time point t30, and/or the thirty-fifth time point t35 based on the number of times by which adjacent wordline activation with respect to the first to n-th wordlines WL1 to WLn has occurred during a bank refresh interval (e.g., a normal bank refresh interval PN_REF) before the twentieth time point t20. However, the example embodiments are not limited thereto.

In some example embodiments, at the twenty-fifth time point t25, the thirtieth time point t30, and/or the thirty-fifth time point t35, the row hammering protector 170 may issue the additional refresh command CMD_AREF and/or the row addresses corresponding thereto based on gradually higher probabilities. For example, the row hammering protector 170 may perform the additional refresh operation with respect to each, or one or more, of the plurality of wordlines with a higher probability at the thirtieth time point t30 than at the twenty-fifth time point t25; and the row hammering protector 170 may perform the additional refresh operation with respect to each, or one or more, of the plurality of wordlines with a higher probability at the thirty-fifth time point t35 than at the thirtieth time point t30. For a more specific example, the row hammering protector 170 may perform the additional refresh operation with respect to each, or one or more, of the plurality of wordlines at the twenty-fifth time point t25 based on probabilities previously determined based on the tenth to twentieth time points t10 to t20; and may perform the additional refresh operation with respect to each, or one or more, of the plurality of wordlines at the thirtieth time point t30 based on a value obtained by multiplying a predetermined, or alternately given, scale coefficient to the probability described above. However, example embodiments are not limited to a specific method in which the row hammering protector 170 determines the additional refresh probability with respect to the plurality of wordlines at each of the plurality of time points.

That is, according to some example embodiments of the inventive concepts, the additional refresh operation may be performed multiple times within one bank refresh period. In this case, the possibility of damage to the data stored in the memory device 100 due to row hammering may be reduced or minimized.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The above-described contents are example embodiments for implementing the inventive concepts. The inventive concepts will include not only the above-described example embodiments, but also embodiments that may be simply design-changed or easily changed. In addition, inventive concepts will also include techniques that may be easily modified and implemented by using the example embodiments. While the inventive concepts have been described with reference to example embodiments thereof, it will be apparent to those of ordinary skill in the art that various changes and modifications may be made thereto without departing from the spirit and scope of the inventive concepts as set forth in the following claims.

What is claimed is:

1. A memory device, comprising:
a memory cell array connected to a plurality of wordlines; and
a row hammering protector including processing circuitry configured to probabilistically perform, based on an adjacent wordline activation count with respect to each of the plurality of wordlines during a first bank refresh period, an additional refresh operation with respect to each of the plurality of wordlines within a second bank refresh period after the first bank refresh period.

2. The memory device of claim 1, wherein the row hammering protector comprises:
a probability memory configured to store a global probability table, the global probability table including a plurality of probabilities corresponding to a plurality of count ranges, respectively; and
a first row hammering protection circuit configured to issue a first row refresh command with respect to a first wordline, of the plurality of wordlines, within the second bank refresh period, based on the global probability table and a first number of times wordlines adjacent to the first wordline are activated during the first bank refresh period.

3. The memory device of claim 2, wherein the row hammering protector further comprises:
a second row hammering protection circuit configured to probabilistically issue a second row refresh command with respect to a second wordline, of the plurality of wordlines, within the second bank refresh period, based on the global probability table and a second number of times wordlines adjacent to the second wordline are activated during the first bank refresh period.

4. The memory device of claim 3, wherein,
the first row hammering protection circuit is further configured to:
identify a first probability corresponding to a count range, among the plurality of count ranges, including a first count value, the first count value corresponding with the first number; and
issue the first row refresh command within the second bank refresh period according to the first probability, and
the second row hammering protection circuit is further configured to:
identify a second probability corresponding to a count range, among the plurality of count ranges, including a second count value, the second count value corresponding with the second number; and
issue the second row refresh command within the second bank refresh period according to the second probability.

5. The memory device of claim 4, wherein:
the first row refresh command comprises a first activation command for the first wordline, and a first precharge command for the memory cell array; and
the second row refresh command comprises a second activation command for the second wordline, and a second precharge command for the memory cell array.

6. The memory device of claim 4, wherein:
the first row hammering protection circuit is further configured to
store a first local probability table corresponding to a first portion of the global probability table, and
determine the first probability based on a count range corresponding to the first count value among count ranges included in the first local probability table; and
the second row hammering protection circuit is further configured to store a second local probability table corresponding to a second portion of the global probability table, and
determine the second probability based on a count range corresponding to the second count value among count ranges included in the second local probability table.

7. The memory device of claim 6, wherein:
the first row hammering protection circuit is further configured to dynamically adjust each of the count ranges included in the first local probability table based on the first count value; and
the second row hammering protection circuit is further configured to dynamically adjust each of the count ranges included in the second local probability table based on the second count value.

8. The memory device of claim 6, wherein:
the first row hammering protection circuit is further configured to update the first local probability table based on a third portion of the global probability table in response to the first count value being out of the count ranges included in the first local probability table; and
the second row hammering protection circuit is further configured to update the second local probability table based on a fourth portion of the global probability table in response to the second count value being out of the count ranges included in the second local probability table.

9. The memory device of claim 2, wherein:
the plurality of count ranges comprises a first plurality of count ranges and a second plurality of count ranges higher than the first plurality of count ranges;
the plurality of probabilities comprises a first plurality of probabilities corresponding to the first plurality of count ranges and a second plurality of probabilities corresponding to the second plurality of count ranges;
upper limit values of the first plurality of count ranges are a first plurality of upper limit values, respectively;
upper limit values of the second plurality of count ranges are a second plurality of upper limit values, respectively; and
a first ratio of a second value to a first value is greater than a second ratio of a fourth value to a third value, wherein
the second value corresponds with a difference between a greatest probability of the first plurality of probabilities and a smallest probability of the first plurality of probabilities,
the first value corresponds with a difference between a greatest upper limit value of the first plurality of upper limit values and a smallest upper limit value of the first plurality of upper limit values,
the fourth value corresponds with a difference between a greatest probability of the second plurality of probabilities and a smallest probability of the second plurality of probabilities, and
the third value corresponds with a difference between a greatest upper limit value of the second plurality of upper limit values and a smallest upper limit value of the second plurality of upper limit values.

10. The memory device of claim 9, wherein:
the first plurality of probabilities is logarithmic with respect to the first plurality of upper limit values; and
the second plurality of probabilities is linear with respect to the second plurality of upper limit values.

11. The memory device of claim 9, wherein sizes of the first plurality of count ranges are smaller than or equal to sizes of the second plurality of count ranges.

12. The memory device of claim 9, wherein a size of a first count range, of the first plurality of count ranges, is smaller than or equal to a size of a second count range among the first plurality of count ranges.

13. A memory device configured to operate in response to control from an external device, the memory device comprising:
a memory cell array connected to a plurality of wordlines; and
processing circuitry configured to
generate a first count value by counting the number of times of an activation command for second and third wordlines adjacent to a first wordline among the plurality of wordlines is received from the external device, between a first time point at which a first bank refresh command is received from the external device and a second time point at which a second bank refresh command is received from the external device;
determine a first probability corresponding to the first count value; and
issue a first row refresh command for the first wordline according to the first probability, at a fourth time point between the second time point and a third time point at which a third bank refresh command is received from the external device.

14. The memory device of claim 13, wherein:
the memory device further comprises a probability memory configured to store a global probability table comprising a plurality of probabilities corresponding to a plurality of count ranges, respectively; and
the processing circuitry is further configured to determine the first probability based on a count range corresponding to the first count value among the plurality of count ranges.

15. The memory device of claim 13, wherein a time interval between the second time point and the fourth time point is a first time length.

16. The memory device of claim 15, wherein the processing circuitry is further configured to issue a second row refresh command for the first wordline at a fifth time point according to a second probability determined based on the first probability, in response to the fifth time point, after the first time length has elapsed from the fourth time point, being ahead of the third time point.

17. The memory device of claim 16, wherein the second probability is higher than or equal to the first probability.

18. The memory device of claim 13, wherein the first row refresh command comprises an activation command for the first wordline, and a precharge command for the memory cell array.

19. The memory device of claim 18, wherein the processing circuitry is further configured to generate a first additional refresh command comprising a target row refresh (TRR) mode enter command and the first row refresh command.

20. A memory device configured to receive first and second bank refresh commands from an external device at first and second time points, respectively, the memory device comprising:
a memory cell array connected to first and second aggressor wordlines, and a victim wordline located between the first and second aggressor wordlines; and
processing circuitry configured to probabilistically issue, based on a number of times of activation commands for the first and second aggressor wordlines are received between the first and the second time points, a row refresh command for the victim wordline at each time interval from the second time point until a third bank refresh command is received.
